(19) United States
(12) Patent Application Publication
(10) Pub. No.: US 2012/0032246 A1
(43) Pub. Date: Feb. 9, 2012

(54) NONVOLATILE SEMICONDUCTOR MEMORY DEVICE AND METHOD OF MANUFACTURING THE SAME

(75) Inventors: Masashi HONDA, Yokkaichi-shi (JP); Hitoshi Ito, Yokkaichi-shi (JP); Hideyuki Kinoshita, Yokkaichi-shi (JP)

(73) Assignee: KABUSHIKI KAISHA TOSHIBA, Tokyo (JP)

(21) Appl. No.: 13/196,084

(22) Filed: Aug. 2, 2011

(30) Foreign Application Priority Data
Aug. 5, 2010 (JP) 2010-175970

(51) Int. Cl. H01L 29/788; H01L 21/336

(52) U.S. Cl. 257/316; 438/593; 257/E29.3; 257/E21.422

(57) ABSTRACT

A nonvolatile semiconductor memory device according to an embodiment includes a semiconductor substrate, a memory cell transistor formed in a memory cell region, and a field-effect transistor formed in a peripheral circuit region. The memory cell transistor includes: a floating gate electrode; a first inter-electrode insulating film; and a control gate electrode. The field-effect transistor includes: a lower gate electrode; a second inter-electrode insulating film having an opening; and an upper gate electrode electrically connected to the lower gate electrode via the opening. The control gate electrode and the upper gate electrode are formed by a plurality of conductive films that are stacked. The control gate electrode and the upper gate electrode include a barrier film formed in one of interfaces between the stacked conductive films and configured to suppress diffusion of metal atoms. The control gate electrode and the upper gate electrode have a part that is silicided.

### CROSS REFERENCE TO RELATED APPLICATION

This application is based upon and claims the benefit of priority from prior Japanese Patent Application No. 2010-175970, filed on Aug. 5, 2010, the entire contents of which are incorporated herein by reference.

### FIELD

Embodiments described in the present specification relate to a nonvolatile semiconductor memory device and a method of manufacturing the same.

### DESCRIPTION OF THE RELATED ART

NAND-type flash memory is known as a nonvolatile semiconductor memory device (EEPROM) that is electrically rewritable and capable of a high degree of integration. In NAND-type flash memory, a plurality of memory cells are connected in series such that adjacent memory cells share source/drain regions, thereby configuring a NAND cell unit. The two ends of the NAND cell unit are respectively connected to a bit line and a source line via select gate transistors. Such a NAND cell unit configuration allows a smaller unit cell area and larger storage capacity than a NOR-type flash memory.

Provided in a periphery of the memory cell region for storing information are peripheral circuits for controlling operation of the NAND-type flash memory. Field-effect transistors formed in the peripheral circuit region are formed by processes similar to those for memory transistors or select gate transistors. A configuration in which gate electrodes are silicided for improving performance of these field-effect transistors in the peripheral circuit region and memory cell transistors is known.

In the silicide process of a nonvolatile semiconductor memory device, a difference sometimes occurs in growth speed of silicide between the memory cell region and the peripheral circuit region. If growth speed of silicide differs, there are cases where, even if sufficient silicide can be formed in a field-effect transistor in the peripheral circuit region, siliciding proceeds excessively in a memory transistor in the memory cell region. As a result, a void is formed in the gate electrode of the memory transistor and performance of the memory transistor is degraded.

Conversely, there are also cases where, even if an appropriate amount of silicide is formed in the memory transistor, only an insufficient amount of silicide is formed in the field-effect transistor. Therefore, in the silicide process of the nonvolatile semiconductor memory device, it is required that a sufficient amount of silicide is formed in the peripheral circuit region, while growth speed of silicide in the memory cell region is suppressed.

### BRIEF DESCRIPTION OF THE DRAWINGS

FIG. 1 is a diagram showing a memory cell region and a peripheral circuit region in a nonvolatile semiconductor memory device according to a first embodiment.

FIG. 2A is an equivalent circuit diagram showing a memory cell array in the nonvolatile semiconductor memory device according to the first embodiment.

FIG. 2B is a layout diagram of the memory cell array in the nonvolatile semiconductor memory device according to the first embodiment.

FIG. 3 is a layout diagram showing part of the peripheral circuit region in the nonvolatile semiconductor memory device according to the first embodiment.

FIG. 4 is a cross-sectional view of the memory cell array in the nonvolatile semiconductor memory device according to the first embodiment.

FIG. 5 is a cross-sectional view of the memory cell array in the nonvolatile semiconductor memory device according to the first embodiment.

FIG. 6 is a cross-sectional view of part of the peripheral circuit region in the nonvolatile semiconductor memory device according to the first embodiment.

FIG. 7 is a cross-sectional view showing a method of manufacturing a nonvolatile semiconductor memory device according to the first embodiment.

FIG. 8 is a cross-sectional view showing the method of manufacturing a nonvolatile semiconductor memory device according to the first embodiment.

FIG. 9 is a cross-sectional view showing the method of manufacturing a nonvolatile semiconductor memory device according to the first embodiment.

FIG. 10 is a cross-sectional view showing the method of manufacturing a nonvolatile semiconductor memory device according to the first embodiment.

FIG. 11 is a cross-sectional view showing the method of manufacturing a nonvolatile semiconductor memory device according to the first embodiment.

FIG. 12 is a cross-sectional view showing the method of manufacturing a nonvolatile semiconductor memory device according to the first embodiment.

FIG. 13 is a cross-sectional view showing a method of manufacturing a nonvolatile semiconductor memory device in a comparative example.

FIG. 14 is a cross-sectional view showing the method of manufacturing a nonvolatile semiconductor memory device in the comparative example.

FIG. 15 is a cross-sectional view showing the method of manufacturing a nonvolatile semiconductor memory device in the comparative example.

FIG. 16 is a cross-sectional view showing the method of manufacturing a nonvolatile semiconductor memory device in the comparative example.

FIG. 17 is a cross-sectional view showing the method of manufacturing a nonvolatile semiconductor memory device in the comparative example.

FIG. 18 is a cross-sectional view showing a method of manufacturing a nonvolatile semiconductor memory device according to another example of the first embodiment.

FIG. 19 is a cross-sectional view showing the method of manufacturing a nonvolatile semiconductor memory device according to another example of the first embodiment.

FIG. 20 is a cross-sectional view showing a method of manufacturing a nonvolatile semiconductor memory device according to a second embodiment.

FIG. 21 is a cross-sectional view showing the method of manufacturing a nonvolatile semiconductor memory device according to the second embodiment.

FIG. 22 is a cross-sectional view showing the method of manufacturing a nonvolatile semiconductor memory device according to the second embodiment.

FIG. 23 is a cross-sectional view showing the method of manufacturing a nonvolatile semiconductor memory device according to the second embodiment.

FIG. 24 is a cross-sectional view showing a method of manufacturing a nonvolatile semiconductor memory device according to a third embodiment.

FIG. 25 is a cross-sectional view showing the method of manufacturing a nonvolatile semiconductor memory device according to the third embodiment.

FIG. 26 is a cross-sectional view showing the method of manufacturing a nonvolatile semiconductor memory device according to the third embodiment.

FIG. 27 is a cross-sectional view showing the method of manufacturing a nonvolatile semiconductor memory device according to the third embodiment.

FIG. 28 is a cross-sectional view showing the method of manufacturing a nonvolatile semiconductor memory device according to the third embodiment.

FIG. 29 is a cross-sectional view showing a method of manufacturing a nonvolatile semiconductor memory device according to another example of the third embodiment.

FIG. 30 is a cross-sectional view showing a method of manufacturing a nonvolatile semiconductor memory device according to a fourth embodiment.

FIG. 31 is a cross-sectional view showing the method of manufacturing a nonvolatile semiconductor memory device according to the fourth embodiment.

FIG. 32 is a cross-sectional view showing the method of manufacturing a nonvolatile semiconductor memory device according to the fourth embodiment.

FIG. 33 is a cross-sectional view showing the method of manufacturing a nonvolatile semiconductor memory device according to the fourth embodiment.

FIG. 34 is a cross-sectional view showing a method of manufacturing a nonvolatile semiconductor memory device according to another example of the fourth embodiment.

FIG. 35 is a cross-sectional view showing the method of manufacturing a nonvolatile semiconductor memory device according to another example of the fourth embodiment.

### DETAILED DESCRIPTION

A nonvolatile semiconductor memory device according to an embodiment comprises a semiconductor substrate, a memory cell transistor formed in a memory cell region, and a field-effect transistor formed in a peripheral circuit region. The memory cell transistor includes: a floating gate electrode formed on the semiconductor substrate via a first gate insulating film; a first inter-electrode insulating film disposed on the floating gate electrode; and a control gate electrode disposed on the first inter-electrode insulating film. The field-effect transistor includes: a lower gate electrode formed on the semiconductor substrate via a second gate insulating film; a second inter-electrode insulating film disposed on the lower gate electrode and having an opening; and an upper gate electrode disposed on the second inter-electrode insulating film and electrically connected to the lower gate electrode via the opening. The control gate electrode and the upper gate electrode are formed by a plurality of conductive films that are stacked. The control gate electrode and the upper gate electrode include a barrier film formed in at least one of interfaces between the stacked plurality of conductive films and configured to suppress diffusion of metal atoms. The control gate electrode and the upper gate electrode have a part that is silicided.

Next, embodiments of the present invention are described in detail with reference to the drawings. The embodiments are described taking a NAND-type flash memory as an example. However, the present invention is not limited to this example, and may also be applied to other semiconductor memory devices having a so-called floating gate structure. Note that in notation of the drawings in the embodiments below, identical symbols are assigned to places having identical configurations, and redundant descriptions thereof are omitted. Moreover, the drawings are schematic, and the relationship between thicknesses of each of films and planar dimensions, ratios of thicknesses of each of layers, and so on, differ from those in an actual nonvolatile semiconductor memory device.

### First Embodiment

### Configuration of Nonvolatile Semiconductor Memory Device According to First Embodiment

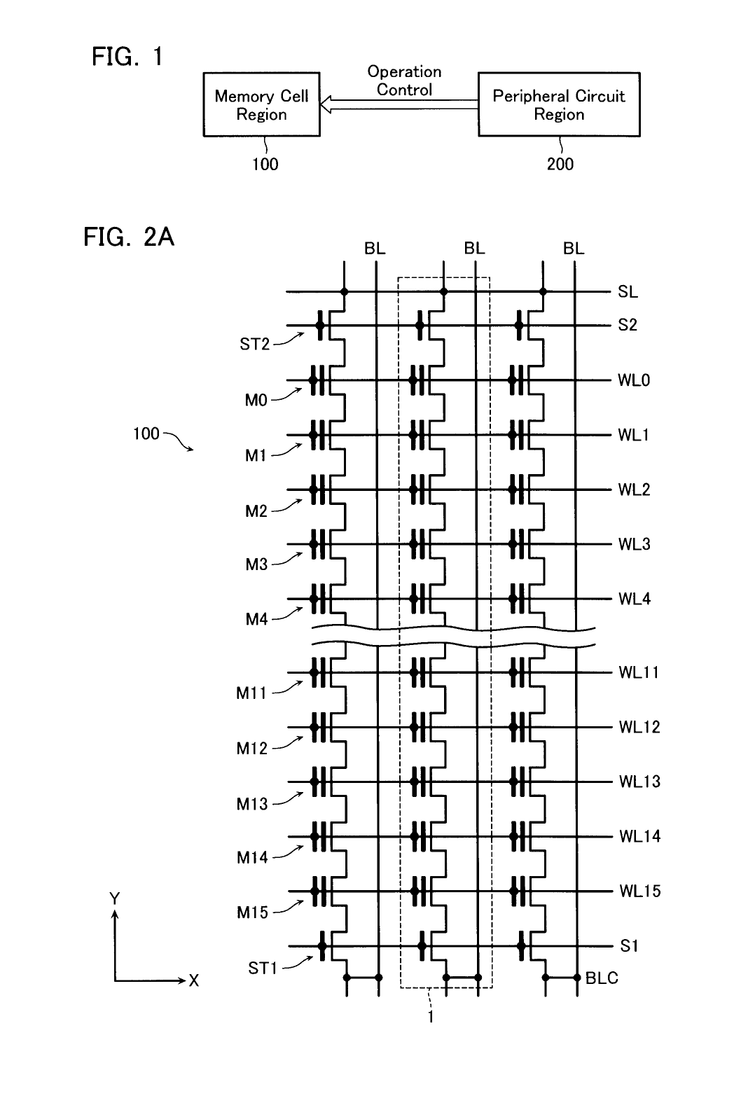

A configuration of a nonvolatile semiconductor memory device according to a first embodiment of the present invention is now described with reference to FIGS. 1-6. First, a configuration of a NAND-type flash memory in the present embodiment is described.

FIG. 1 is a block diagram showing the nonvolatile semiconductor memory device in its entirety. As shown in FIG. 1, the nonvolatile semiconductor memory device includes a memory cell region 100 employed for storing information, and a peripheral circuit region 200 employed for control of each of operations of write/erase/read of information to/in/from the memory cell region 100. Formed in the memory cell region 100 is a memory cell array to be described later. Moreover, formed in the peripheral circuit region 200 are a row decoder, a column decoder, a voltage generating circuit, an interface for transmitting and receiving various kinds of commands/addresses/data, and so on.

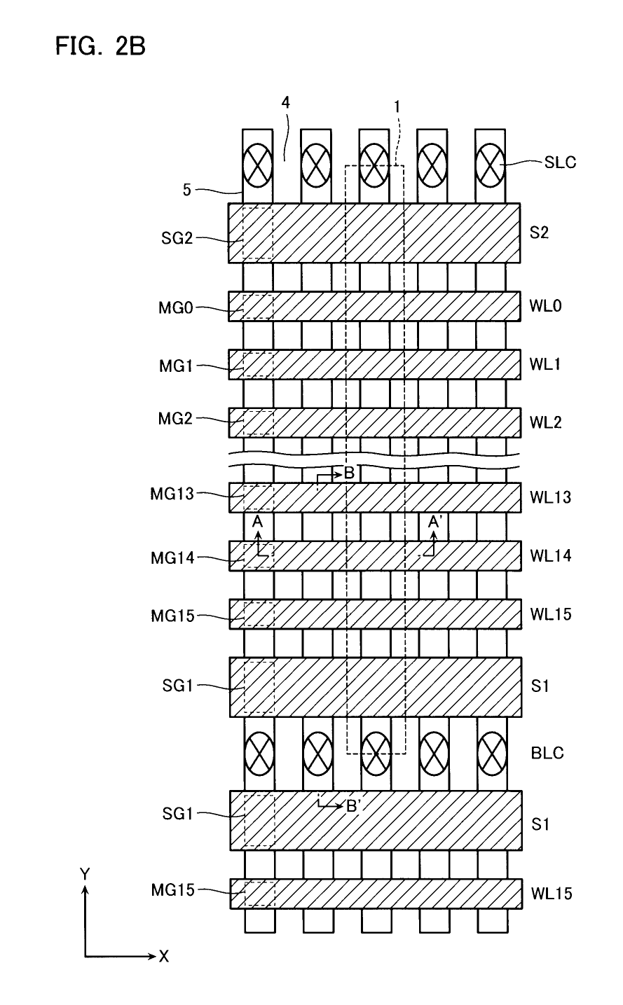

FIG. 2A is an equivalent circuit diagram showing part of a memory cell array formed in the memory cell region 100 of the NAND-type flash memory. A NAND cell unit 1 in the NAND-type flash memory is configured from two select gate transistors ST1 and ST2, and a plurality of memory cell transistors Mn (n is an integer from 0 to 15, similarly hereinafter) connected in series between the select gate transistors ST1 and ST2. In the NAND cell unit 1, the plurality of memory cell transistors Mn are formed such that adjacent ones of the memory cell transistors Mn share source/drain regions. The memory cell array is configured having the NAND cell units 1 arranged in a matrix.

Control gate electrodes of the memory cell transistors Mn arranged in an X direction (corresponding to a gate width direction) in FIG. 2A are commonly connected by word lines WLn, respectively. In addition, gate electrodes of the select gate transistors ST1 arranged in the X direction in FIG. 2A are commonly connected by a select gate line S1, and gate electrodes of the select gate transistors ST2 arranged in the X direction in FIG. 2A are commonly connected by a select gate line S2. A bit line contact BLC is connected to a drain region of the select gate transistor ST1. This bit line contact BLC is connected to a bit line BL extending in a Y direction (corresponding to a gate length direction) orthogonal to the X direction in FIG. 2A. Moreover, the select gate transistor ST2 is connected via a source region to a source line SL extending in the X direction in FIG. 2A.

The memory cell transistor Mn is assumed to have a stacked gate structure, that is, the memory cell transistor Mn is assumed to include n-type source/drain regions formed in a p-type well 3 in a silicon substrate, and to include a floating gate electrode acting as a charge storage layer, and a control gate electrode. In the NAND-type flash memory, an amount of charge stored in the floating gate electrode is changed by a write operation and an erase operation. This causes a threshold voltage of the memory cell transistor Mn to be changed, whereby single-bit or multi-bit data is stored in the memory cell transistor Mn. In the NAND-type flash memory, an assembly of a plurality of NAND cell units 1 sharing word lines WL configures a block. Erase of data in the NAND-type flash memory is executed in units of this block.

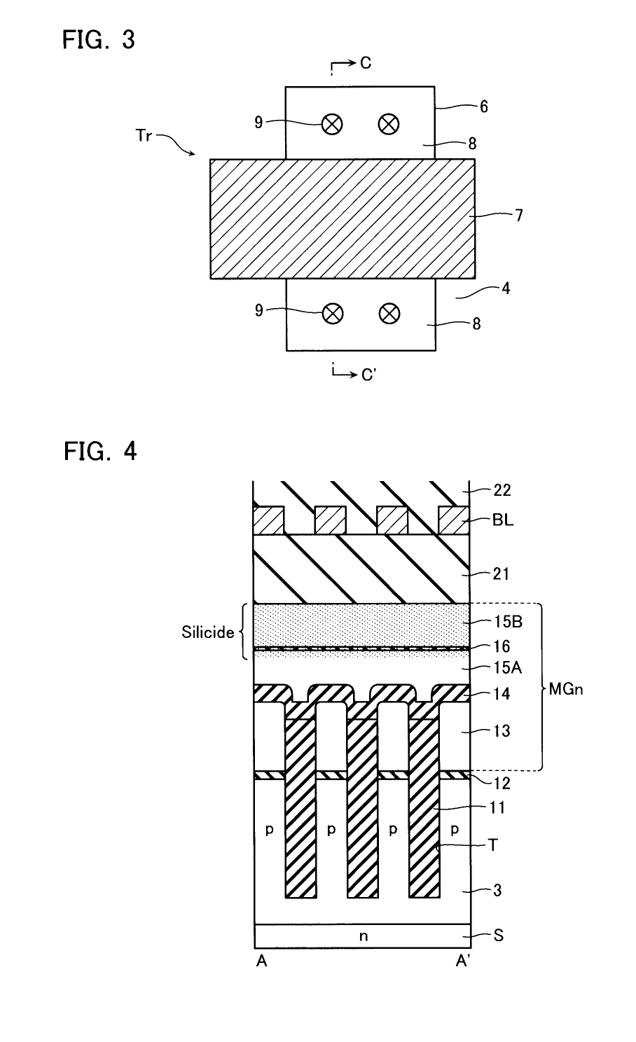

FIG. 2B is a layout diagram of part of the memory cell array formed in the memory cell region 100 of the NAND-type flash memory. FIG. 3 is a layout diagram of a field-effect transistor formed in the peripheral circuit region 200 of the NAND-type flash memory.

As shown in FIG. 2B, a plurality of element isolation regions 4 having an STI (Shallow Trench Isolation) structure and extending along the Y direction in FIG. 2B are formed in the silicon substrate (semiconductor substrate) having a certain spacing in the X direction. As a result, element regions 5 are formed isolated in the X direction in FIG. 2B. In addition, the word lines WLn of the memory cell transistors Mn extending along the X direction in FIG. 2B are formed having a certain spacing in the Y direction. On the element region 5 where the element region 5 intersects the word line WLn, the word line WLn functions as a gate electrode MGn of the memory cell transistor Mn. Moreover, the select gate line S1 of the select gate transistor ST1 is formed so as to extend along the X direction in FIG. 2B. On the element region 5 where the element region 5 intersects the select gate line S1, the select gate line 51 functions as a gate electrode SG1 of the select gate transistor ST1. The bit line contact BLC is formed in each of the element regions 5 between adjacent select gate lines S1. This bit line contact BLC is connected to the bit line BL (not shown) extending in the Y direction in FIG. 2B. In addition, the select gate line S2 of the select gate transistor ST2 is formed so as to extend along the X direction in FIG. 2B. On the element region 5 where the element region 5 intersects the select gate line S2, the select gate line S2 functions as a gate electrode SG2 of the select gate transistor ST2. A source line contact SLC is formed in each of the element regions 5 between adjacent select gate lines S2. This source line contact SLC is connected to the source line SL (not shown) extending in the X direction in FIG. 2B.

Next, a structure of a field-effect transistor Tr formed in the peripheral circuit region 200 is described. As shown in FIG. 3, the field-effect transistor Tr formed in the peripheral circuit region 200 is provided on an element region 6 left in a rectangular shape in the silicon substrate (semiconductor substrate). The element isolation region 4 is formed so as to surround this element region 6. Each element region 6 has a gate electrode 7 formed thereon so as to cross the element region 6, and has source/drain regions 8 provided therein on both sides of the gate electrode region 7, the source/drain regions 8 being formed by diffusing impurities. Contact plugs 9 are formed in the source/drain regions 8.

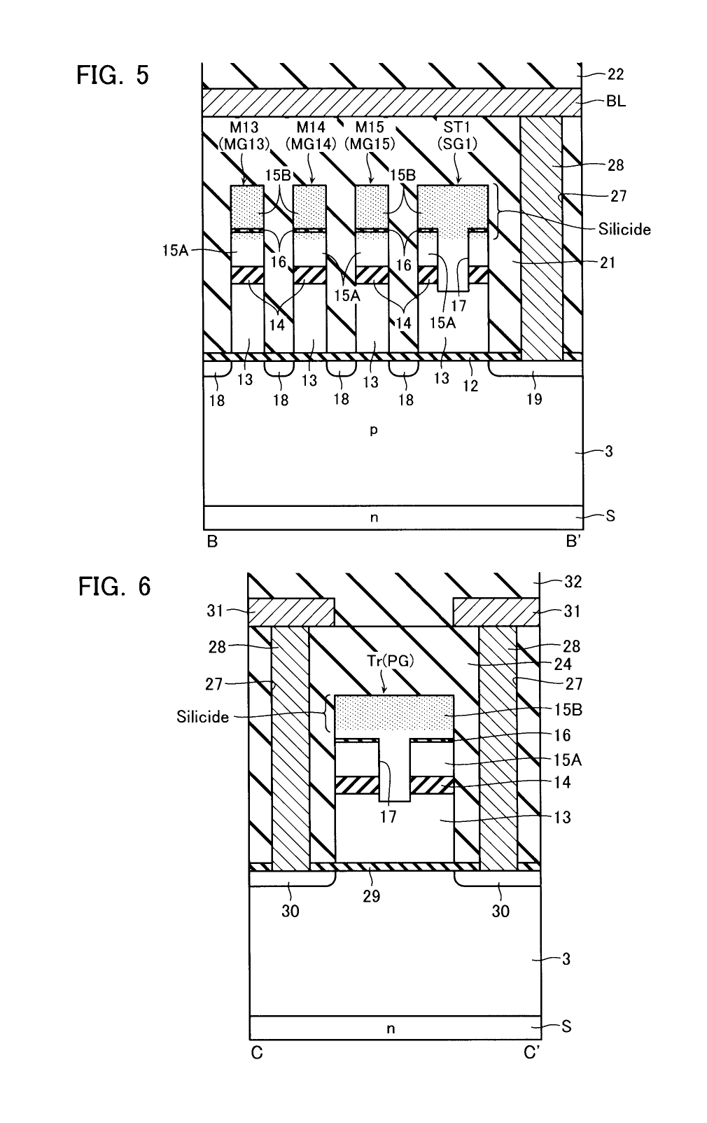

FIGS. 4-6 are cross-sectional views taken along the line A-A′, the line B-B′, and the line C-C′, respectively, shown in FIGS. 2B and 3. FIG. 4 is a cross-sectional view of part of the memory cell array in the NAND-type flash memory taken along the X direction in FIG. 2B. FIG. 5 is a cross-sectional view of part of the memory cell array in the NAND-type flash memory taken along the Y direction in FIG. 2B. FIG. 6 is a cross-sectional view of the field-effect transistor Tr formed in the peripheral circuit region 200 of the NAND-type flash memory. Note that a length of a polysilicon film 13 in the memory cell transistor Mn in a B-B′ line direction is termed gate length of the memory transistor, and a length of a polysilicon film 13 in the field-effect transistor Tr in a C-C′ line direction is termed gate length of the field-effect transistor.

As shown in FIG. 4, the p-type well 3 is formed on a silicon substrate S in the memory cell region 100. Trenches T are formed equally spaced in this p-type well 3, and each of these trenches T is filled in by an element isolation insulating film 11. A region filled by the element isolation insulating film 11 becomes the above-mentioned element isolation region 4. Formed above the p-type well 3 sandwiched by this element isolation insulating film 11 is the memory cell transistor Mn. That is, the p-type well 3 sandwiched by the element isolation insulating film 11 functions as the element region 5 in which the memory cell transistor Mn, the select gate transistor ST1, and so on are formed.

As shown in FIGS. 4 and 5, a tunnel insulating film 12 is formed on the p-type well 3. Formed, via this tunnel insulating film 12, are the gate electrode MGn (n is an integer between 0 and 15, similarly hereinafter) of the memory cell transistor Mn, and the gate electrode SG1 of the select gate transistor ST1. These gate electrodes MGn and SG1 have a configuration in which a polysilicon film 13 functioning as the floating gate electrode, an inter-electrode insulating film 14, and polysilicon films 15A and 15B functioning as the control gate electrode are sequentially stacked. The polysilicon films 15A and 15B extend, having a direction perpendicular to the plane of paper in FIG. 5 as a longer direction, to form the word lines WL. In contrast, the polysilicon film 13 is insulated/isolated on a one memory cell transistor Mn basis. Employed as the inter-electrode insulating film 14 is, for example, an ONO structure configured from silicon oxide film—silicon nitride film—silicon oxide film, or an NONON structure having the ONO structure further sandwiched by silicon nitride films. Furthermore, a high-permittivity material, for example, aluminum oxide (Al₂O₃), hafnium silicate (HfSiO), or the like, may be included to increase the coupling ratio of the memory cell transistor Mn.

As shown in FIGS. 4 and 5, a barrier film 16 formed by a method of manufacturing to be described later is present in an interface between the polysilicon films 15A and 15B. The barrier film 16 functions to suppress diffusion of metal atoms in a silicide process.

Additionally, as shown in FIG. 5, an opening 17 is formed in the inter-electrode insulating film 14 in the gate electrode SG1 of the select gate transistor ST1, and this opening 17 is filled in with the polysilicon film 15B. The polysilicon film 13 and the polysilicon films 15A and 15B are electrically connected via this opening 17. Formed in a surface layer (surface) of the p-type well 3 between each of the gate electrodes MGn and between the gate electrodes MG15 and SG1 is an impurity diffusion region 18 that becomes the source/drain region. The impurity diffusion region 18 is formed such that the source/drain region is shared by adjacent memory cell transistors Mn. An impurity diffusion region 19 of high impurity concentration is formed in a surface layer of the silicon substrate S between the gate electrodes SG1 and SG1. Note that the source/drain region between the gate electrodes SG1 and SG1 may be configured having an LDD (Lightly Doped Drain) structure including not only the impurity diffusion region 19 of high impurity concentration, but also a shallow impurity diffusion region of low impurity concentration.

A silicon oxide film 21 functioning as an inter-layer insulating film is formed between each of the gate electrodes MGn and between the gate electrode MG15 and the gate electrode SG1, by an LP-CVD method, for example. These silicon oxide films 21 are formed on the silicon substrate S via the tunnel insulating film 12, and have their upper surfaces planarized using CMP (Chemical Mechanical Polishing), for example.

As shown in FIG. 5, formed in the silicon oxide film 21 between the gate electrodes SG1 and SG1 is a contact hole 27 that reaches a surface of the silicon substrate S. This contact hole 27 is formed to penetrate the silicon oxide film 21 and tunnel insulating film 12 to expose a surface of the impurity diffusion region 19. A contact plug 28 formed by filling in with a conductor is formed inside the contact hole 27 and electrically connected to the impurity diffusion region 19. This contact plug 28 functions as the bit line contact BLC shown in FIG. 2B. Formed on this contact plug 28 is the bit line BL configured from copper (Cu) or aluminum (Al), for example. In FIG. 5, only a contact portion of the bit line side is shown, but a contact portion of the source line side is also connected to the source line SL by a similar configuration. A silicon oxide film 22 functioning as a passivation film is deposited on the bit line BL.

As shown in FIG. 6, a gate insulating film 29 is formed on the p-type well 3 in the peripheral circuit region 200. A gate electrode PG of the field-effect transistor Tr is formed via this gate insulating film 29. The gate insulating film 29 has a film thickness which is larger than a film thickness of the tunnel insulating film 12 formed in the memory cell region 100. This gate electrode PG has a configuration in which a polysilicon film 13 functioning as a lower gate electrode, an inter-electrode insulating film 14, and polysilicon films 15A and 15B functioning as an upper gate electrode are sequentially stacked. Employed as the inter-electrode insulating film 14 is, for example, an ONO structure configured from silicon oxide film—silicon nitride film—silicon oxide film, or an NONON structure having the ONO structure further sandwiched by silicon nitride films.

As shown in FIG. 6, a barrier film 16 formed by a method of manufacturing to be described later is present in an interface between the polysilicon films 15A and 15B. The barrier film 16 functions to suppress diffusion of metal atoms in a silicide process.

An opening 17 is formed also in the inter-electrode insulating film 14 in the gate electrode PG of the field-effect transistor Tr, and this opening 17 is filled in with the polysilicon film 15B. The polysilicon film 13 and the polysilicon films 15A and 15B are electrically connected via this opening 17. Formed in a surface layer (surface) of the p-type well 3 on both sides of the gate electrode PG are impurity diffusion regions 30 that become the previously-mentioned source/drain regions 8. Note that the impurity diffusion region 30 may have an LDD structure. A silicon oxide film 24 functioning as an inter-layer insulating film is formed so as to fill in this gate electrode PG, and has its upper surface planarized using CMP (Chemical Mechanical Polishing), for example.

As shown in FIG. 6, formed on the impurity diffusion region 30 is a contact hole 27 that reaches the surface of the p-type well 3. This contact hole 27 is formed to penetrate the silicon oxide film 24 and gate insulating film 29 to expose a surface of the impurity diffusion region 30. A contact plug 28 formed by filling in with a conductor is formed inside the contact hole 27 and electrically connected to the impurity diffusion region 30. This contact plug 28 functions as the contact plug 9 shown in FIG. 3. Formed on this contact plug 28 is a connection wiring 31 configured from copper (Cu) or aluminum (Al), for example. A silicon oxide film 32 functioning as a passivation film is deposited on the connection wiring 31.

In the above-mentioned nonvolatile semiconductor memory device of the embodiment, the polysilicon films 15A and 15B in the memory cell region 100 and the peripheral circuit region 200 have a part that is silicided. As shown in FIGS. 4 and 5, in the memory cell region 100, all of the polysilicon film 15B and an upper portion of the polysilicon film 15A are silicided. Moreover, as shown in FIG. 6, in the peripheral circuit region 200, only an upper portion of the polysilicon film 15B is silicided. Employed in siliciding of the polysilicon films 15A and 15B is a metal such as nickel (Ni), tungsten (W), titanium (Ti), cobalt (Co), and molybdenum (Mo).

As shown in FIGS. 4-6, in the nonvolatile semiconductor memory device of the present embodiment, a sufficient amount of silicide is formed in the gate electrode PG of the field-effect transistor Tr in the peripheral circuit region 200, while function of the barrier film 16 prevents silicide from reaching the inter-electrode insulating film 14 in the memory cell region 100. Such a method of forming silicide is mentioned in the method of manufacturing a nonvolatile semiconductor memory device below.

[Method of Manufacturing Nonvolatile Semiconductor Memory Device According to First Embodiment]

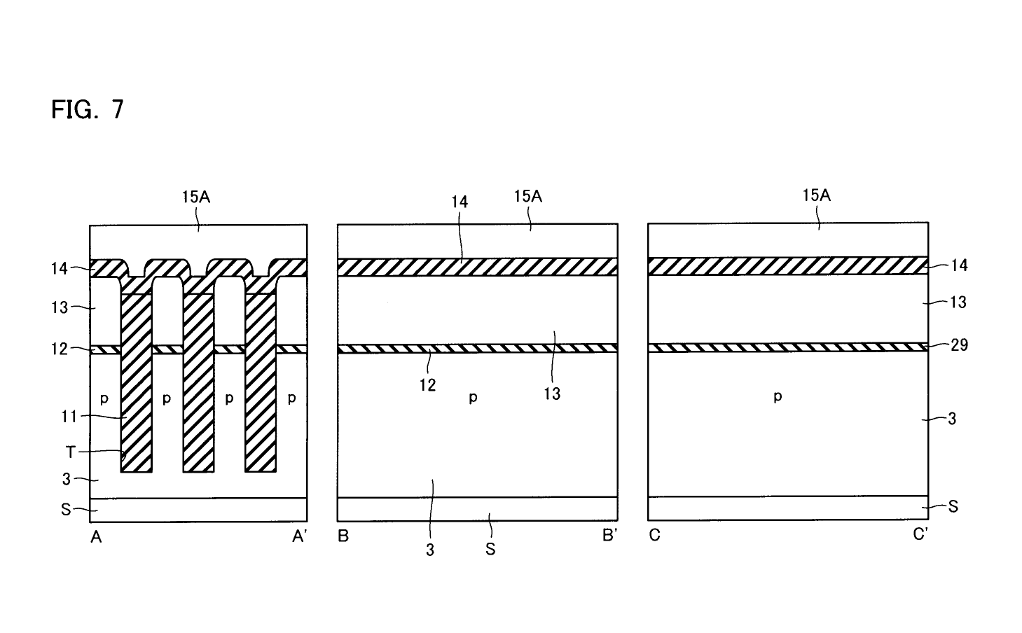

Next, a method of manufacturing a nonvolatile semiconductor memory device in the present embodiment is described with reference to FIGS. 7-11. FIGS. 7-11 are cross-sectional views of manufacturing processes of the memory cell transistor Mn formed in the memory cell region 100 and the field-effect transistor Tr formed in the peripheral circuit region 200. FIGS. 7-11 each show, in alignment, a cross-section taken along the line A-A′ shown in FIG. 2B, a cross-section taken along the line B-B′ shown in FIG. 2B, and a cross-section taken along the line C-C′ shown in FIG. 3. Note that, to simplify description, the cross-section taken along the line B-B′ omits the select gate transistor ST1 and shows only part of the memory cell Mn.

As shown in FIG. 7, a stacking structure of the gate electrodes MGn, SG, and PG is formed. First, ion implantation to form p-type well 3 is performed on the silicon substrate S. Then, as shown in the A-A′ line cross-section and the B-B′ line cross-section, the tunnel insulating film 12 is formed on the p-type well 3 in the memory cell region 100. In addition, as shown in the C-C′ line cross-section, the gate insulating film 29 is formed on the p-type well 3 in the peripheral circuit region 200. Next, the polysilicon film 13 which upon completion of subsequent processes becomes the floating gate electrode in the memory cell transistor Mn or the lower gate electrode in the field-effect transistor Tr is deposited. Subsequently, a well-known lithography method and RIE method are used to form the trench T, and the inside of that trench T is filled with the element isolation insulating film 11 to form the element isolation region 4. Next, to adjust the coupling ratio of the memory cell transistor Mn, the element isolation insulating film 11 within the element isolation region 4 in the memory cell region 100 is etched back. As a result, an upper surface of the element isolation insulating film 11 becomes lower than an upper surface of the polysilicon film 13. Then, an ONO film (stacked film of silicon oxide film—silicon nitride film—silicon oxide film) is deposited as the inter-electrode insulating film 14. In place of the ONO film, an NONON film having a silicon nitride film further added to both sides of the ONO film or an insulating film including a high-permittivity material, such as aluminum oxide (Al₂O₃) or hafnium silicate (HfSiO), may also be adopted. Next, the polysilicon film 15A which upon completion of subsequent processes becomes part of the control gate electrode in the memory cell transistor Mn or part of the upper gate electrode in the field-effect transistor Tr is deposited.

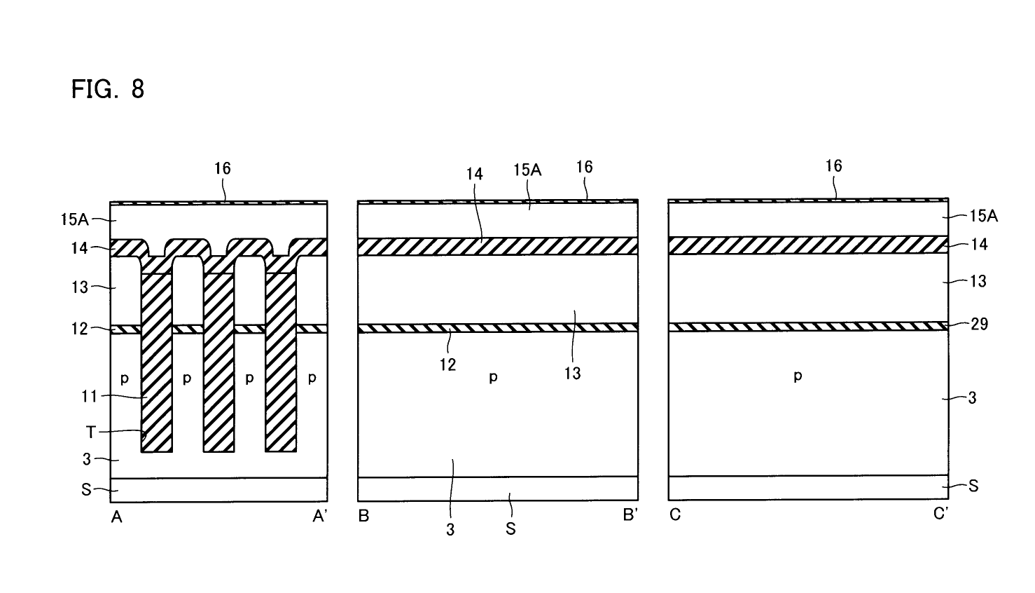

Next, as shown in FIG. 8, the barrier film 16 is formed on the polysilicon film 15A. In a method of manufacturing a semiconductor memory device, interface treatment for reducing effects of an underlying film surface is sometimes performed when a plurality of polysilicon films are stacked. This interface treatment can be used as a formation process of the barrier film 16. The interface treatment oxidizes or cleanses an interface using sulfuric acid and hydrogen peroxide solution as treatment liquids, and this interface treatment allows a silicon oxide film functioning as the barrier film 16 to be formed. This barrier film 16 suppresses diffusion of metal atoms in a subsequent silicide process. The interface treatment may also use the likes of hydrochloric acid and hydrogen peroxide solution as treatment liquids.

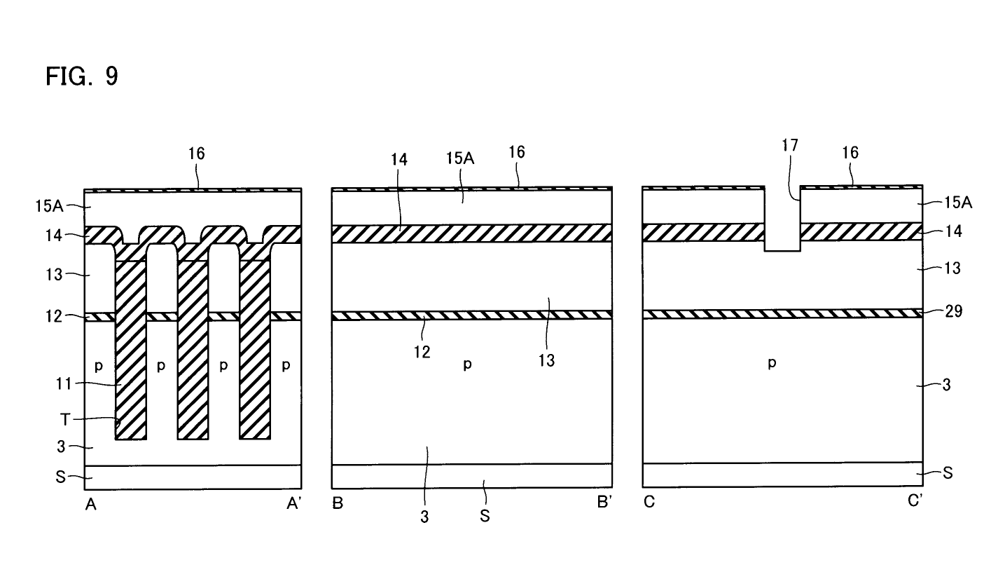

Next, as shown in FIG. 9, in the peripheral circuit region 200, the barrier film 16, the polysilicon film 15A, and the inter-electrode insulating film 14 are penetrated to reach the polysilicon film 13, thereby forming the opening 17. The field-effect transistor Tr in the peripheral circuit region 200 has the polysilicon films 15A and 15B forming the upper gate electrode and the polysilicon film 13 forming the lower gate electrode electrically connected via this opening 17. Note that, although not shown in the A-A′ line cross-section and the B-B′ line cross-section, the opening 17 of the select gate transistors ST1 and ST2 in the memory cell region 100 is also formed at the same time. The opening 17 is formed by the RIE method, and, although a natural oxidation film is sometimes formed during treatment with dilute hydrofluoric acid, this natural oxidation film is too thin (film thickness about 1.0-1.5 nm) to function as a barrier film, and is therefore omitted from FIG. 9. The same applies to description in embodiments below.

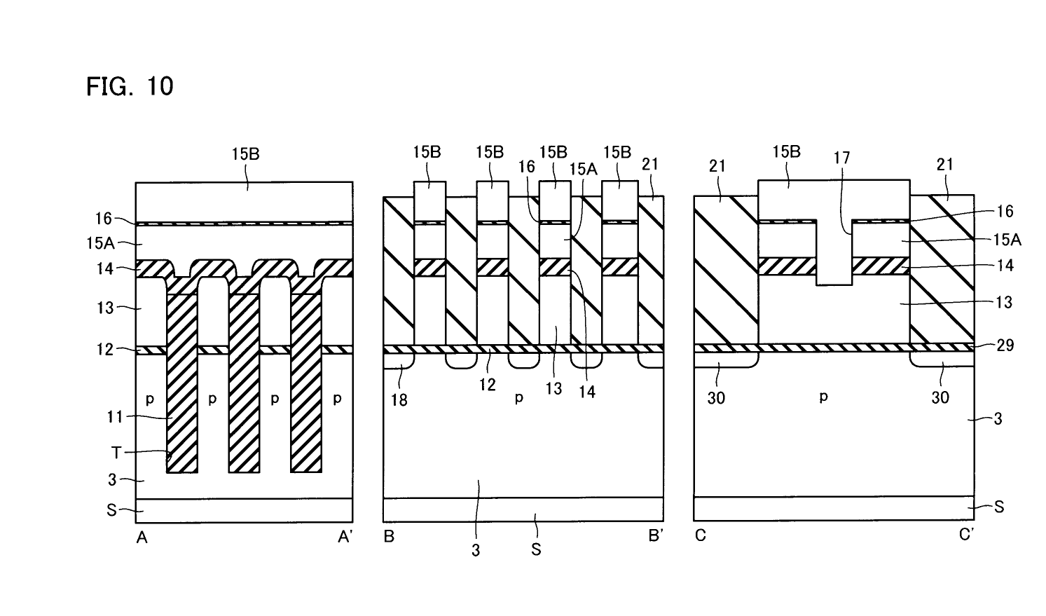

Next, as shown in FIG. 10, the polysilicon film 15B is deposited on the barrier film 16 so as to fill in the opening 17. A thickness of the barrier film 16 is set to allow conducting between the polysilicon films 15A and 15B. Upon completion of processes shown later, these two layers of polysilicon films 15A and 15B become the control gate electrode in the memory cell transistor Mn or the upper gate electrode in the field-effect transistor Tr. Subsequently, a photolithography method and the RIE method are used to perform patterning, and the polysilicon films 15A and 15B, the barrier film 16, the inter-electrode insulating film 14, and the polysilicon film 13 in the memory cell region 100 and the peripheral circuit region 200 are etched sequentially. Then, the impurity diffusion region 18 and the impurity diffusion region 30 are formed by ion implantation, thereby forming the memory cell transistor Mn and the field-effect transistor Tr. When the field-effect transistor Tr is an NMOS transistor, the impurity diffusion region 30 is formed by ion implantation with, for example, arsenic (As) or phosphorus (P), and when the field-effect transistor Tr is a PMOS transistor, the impurity diffusion region 30 is formed by ion implantation with, for example, boron (B) or boron fluoride (BF₂). Next, the space between the patterned gate electrodes MGn in the memory cell region 100 and the patterned gate electrode PG in the peripheral circuit region 200 are filled in by the silicon oxide film 21. The gate electrodes MGn and PG are once all filled in by the silicon oxide film 21. Then, planarization is executed by CMP using a mask material (not shown) on the gate electrodes MGn and PG as a stopper. Next, etching back is performed by the RIE method to remove the mask material on the gate electrodes MGn and PG, and to form an oxide film between the gate electrodes MGn and PG such that part of a side surface of the polysilicon film 15B is left exposed.

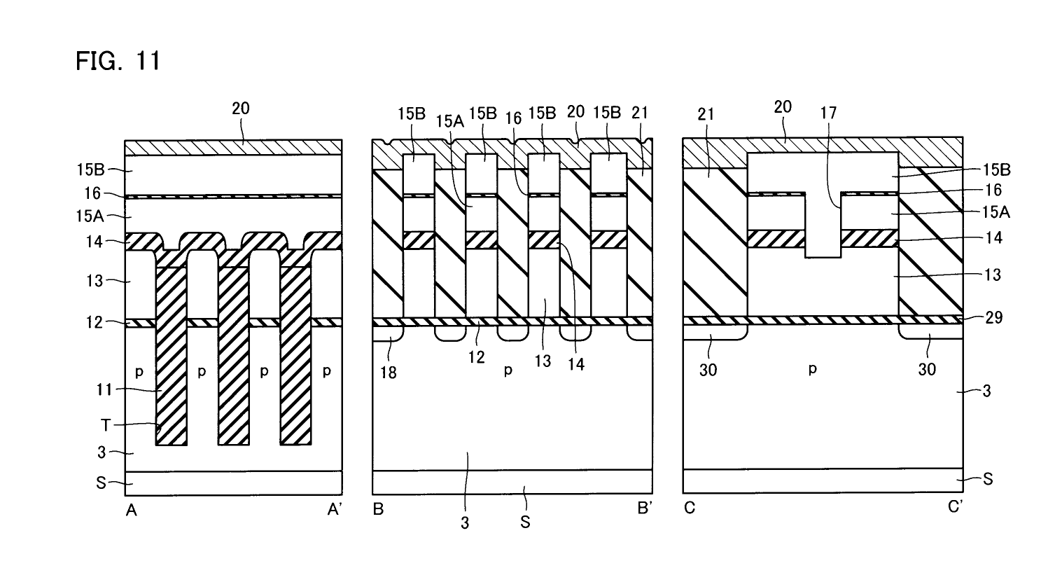

Next, as shown in FIG. 11, a metal film 20 is deposited by sputtering so as to cover the polysilicon film 15B. This metal film 20 is used for diffusing a metal into the polysilicon films 15A and 15B in the subsequent silicide process. As shown in the A-A′ line cross-section and the B-B′ line cross-section, the metal film 20 in the memory cell region 100 is provided so as to be in contact with an upper surface and part of a side surface of the polysilicon film 15B. At the same time, as shown in the C-C′ line cross-section, the metal film 20 in the peripheral circuit region 200 is in contact with an upper surface and part of a side surface of the polysilicon film 15B. Now, a gate length of the field-effect transistor Tr is long compared to a gate length of the memory cell transistor Mn. In the peripheral circuit region 200, the metal film 20 is in a state of being formed almost only on the upper surface of the polysilicon film 15B. In the peripheral circuit region 200, the proportion of metal with respect to the polysilicon film 15B is small compared to in the memory cell region 100.

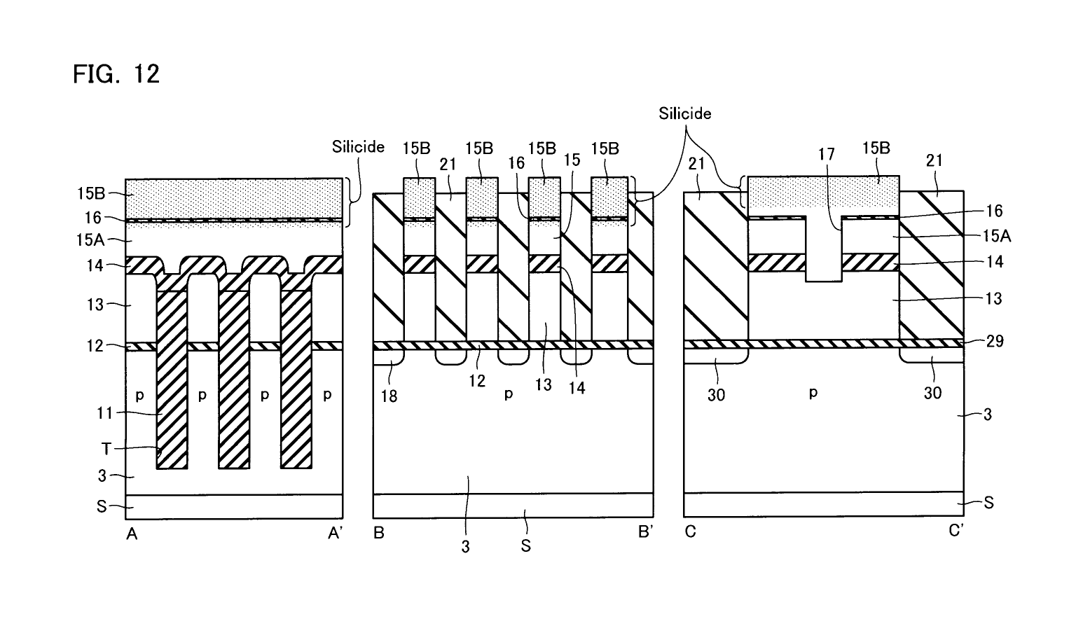

Next, as shown in FIG. 12, an RTP method is used to silicide the polysilicon films 15A and 15B. Now, in the memory cell region 100, the metal film 20 is in contact with the upper surface and the side surface of the polysilicon film 15B, whereby metal atoms are diffused from each of the surfaces. In the memory cell region 100, the proportion of metal with respect to the polysilicon film 15B is large, hence an amount of silicide extending into the polysilicon film 15B is large. On the other hand, in the peripheral circuit region 200, the metal film 20 is in contact mainly with the upper surface of the polysilicon film 15B. In the peripheral circuit region 200, the proportion of metal with respect to the polysilicon film 15B is small compared to in the memory cell region 100, hence an amount of silicide extending into the polysilicon film 15B is small.

Siliciding in the memory cell region 100 extends into an entirety of the polysilicon film 15B and reaches the barrier film 16. Diffusion of metal atoms in the memory cell region 100 is suppressed by this barrier film 16, whereby growth speed of silicide is slowed. As a result, when the silicide process of a certain time has terminated, then, in the memory cell region 100, although part of the polysilicon film 15A is silicided, the silicide process terminates without silicide reaching as far as the inter-electrode insulating film 14. Moreover, in the peripheral circuit region 200, growth speed of silicide is slow, hence the silicide process terminates prior to silicide reaching the barrier film 16.

Manufacturing processes subsequent to those described above comprise well-known manufacturing processes of a nonvolatile semiconductor memory device. The memory cell region 100 and the peripheral circuit region 200 are filled in by the silicon oxide film 21. Then, the contact hole 27 is opened, and the contact plug 28 is formed by filling in the contact hole 27 with the conductor. Upper layer wiring is formed in contact with this contact plug 28 and a passivation film is deposited. This enables the nonvolatile semiconductor memory device of the embodiment shown in FIGS. 4-6 to be manufactured.

[Advantages of Method of Manufacturing Nonvolatile Semiconductor Memory Device According to First Embodiment]

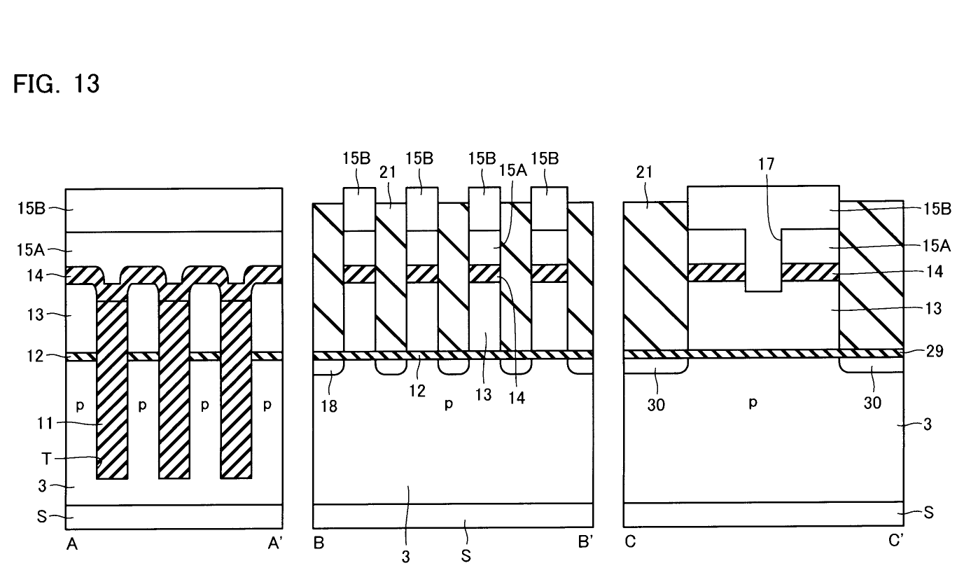

Advantages of the method of manufacturing a NAND-type flash memory according to the present embodiment are described by comparing with a method of manufacturing in a comparative example. FIGS. 13-17 are views describing the method of manufacturing a nonvolatile semiconductor memory device in the comparative example. The method of manufacturing a nonvolatile semiconductor memory device in the comparative example differs from the method of manufacturing a nonvolatile semiconductor memory device in the first embodiment in excluding the process for forming the barrier film 16 shown in FIG. 8. In the method of manufacturing a nonvolatile semiconductor memory device in the comparative example, stacking of the polysilicon films 15A and 15B and formation of the opening 17 are performed by similar processes to those in the above-mentioned embodiment except for the process for forming the barrier film 16.

FIG. 13 is a view showing a state where the polysilicon films 15A and 15B are stacked by the method of manufacturing a nonvolatile semiconductor memory device in the comparative example. As shown in FIG. 13, the method of manufacturing a nonvolatile semiconductor memory device in the comparative example differs from FIG. 10 in there not being a barrier film 16 formed between the polysilicon film 15A and the polysilicon film 15B.

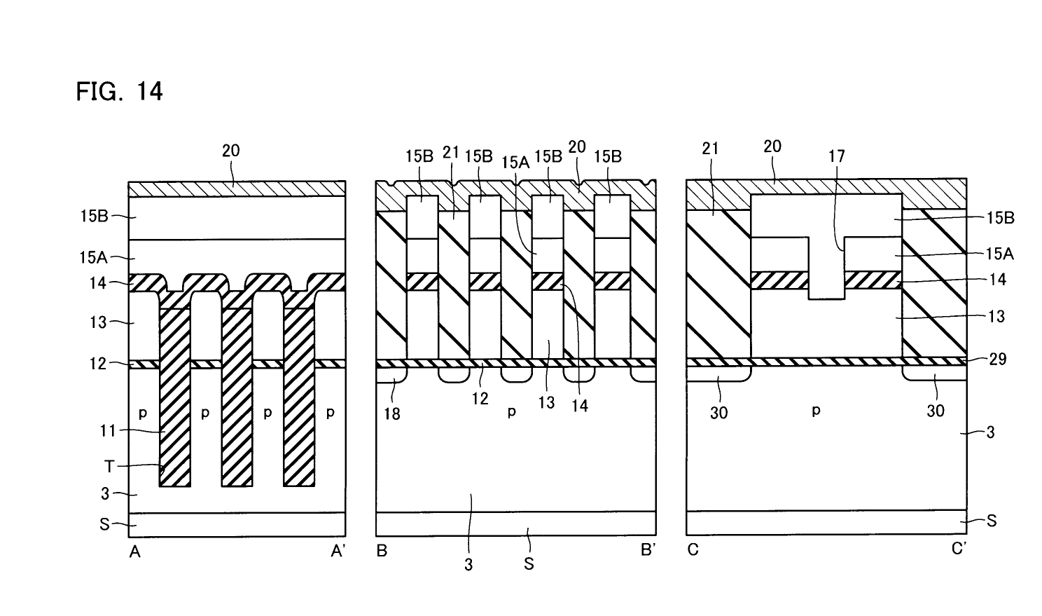

Next, as shown in FIG. 14, the metal film 20 is deposited by sputtering so as to cover the polysilicon film 15B. This metal film 20 is used for diffusing a metal into the polysilicon films 15A and 15B in the subsequent silicide process. As shown in the A-A′ line cross-section and the B-B′ line cross-section, the metal film 20 in the memory cell region 100 is provided so as to be in contact with an upper surface and part of a side surface of the polysilicon film 15B. At the same time, as shown in the C-C′ line cross-section, the metal film 20 in the peripheral circuit region 200 is in contact with an upper surface and part of a side surface of the polysilicon film 15B. Now, a gate length of the field-effect transistor Tr is long compared to a gate length of the memory cell transistor Mn. In the peripheral circuit region 200, the metal film 20 is in a state of being formed almost only on the upper surface of the polysilicon film 15B. In the peripheral circuit region 200, the proportion of metal with respect to the polysilicon film 15B is small compared to in the memory cell region 100.

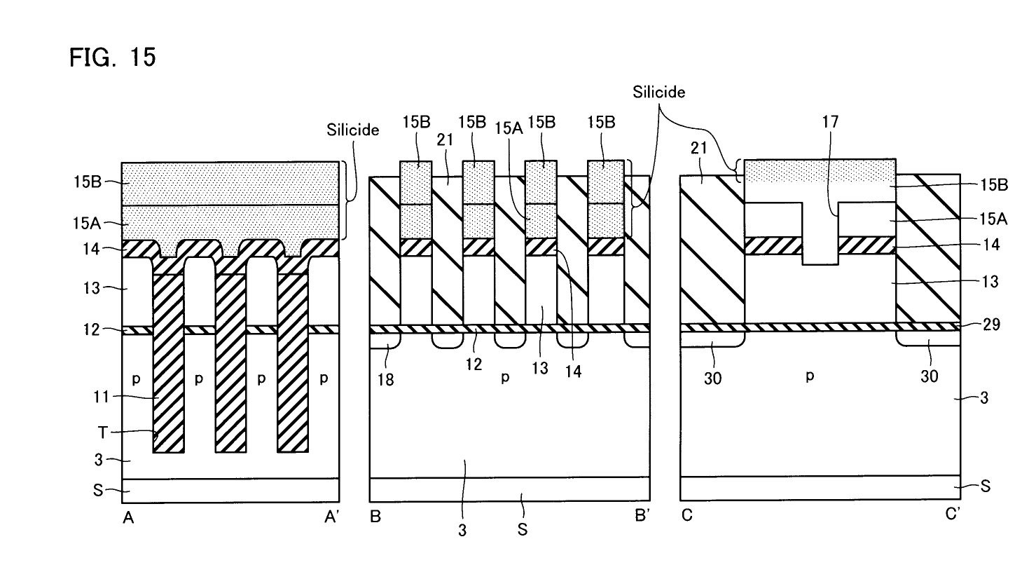

Next, as shown in FIG. 15, an RTP method is used to silicide the polysilicon films 15A and 15B. Now, in the memory cell region 100, the metal film 20 is in contact with the upper surface and the side surface of the polysilicon film 15B, whereby metal atoms are diffused from each of the surfaces. In the memory cell region 100, the proportion of metal with respect to the polysilicon film 15B is large, hence an amount of silicide extending into the polysilicon films 15A and 15B is large. On the other hand, in the peripheral circuit region 200, the metal film 20 is in contact mainly with the upper surface of the polysilicon film 15B. In the peripheral circuit region 200, the proportion of metal with respect to the polysilicon film 15B is small compared to in the memory cell region 100, hence an amount of silicide extending into the polysilicon film 15B is small.

Siliciding in the memory cell region 100 shown in the A-A′ line cross-section and the B-B′ line cross-section extends into an entirety of the polysilicon film 15B. Now, the barrier film 16 is not formed in the method of manufacturing in the comparative example, hence silicide grows further to extend within the polysilicon film 15A. As a result, the polysilicon films 15A and 15B in the memory cell region 100 are fully silicided (FUSI: Full Silicide). The state occurs where, in the memory cell region 100, silicide reaches the inter-electrode insulating film 14. In this state, when silicide grows further, polysilicon in a periphery of a minute void present within the polysilicon films 15A and 15B moves along with silicide growth. As a result, there is a problem that the void in the polysilicon films 15A and 15B becomes larger, whereby performance deteriorates.

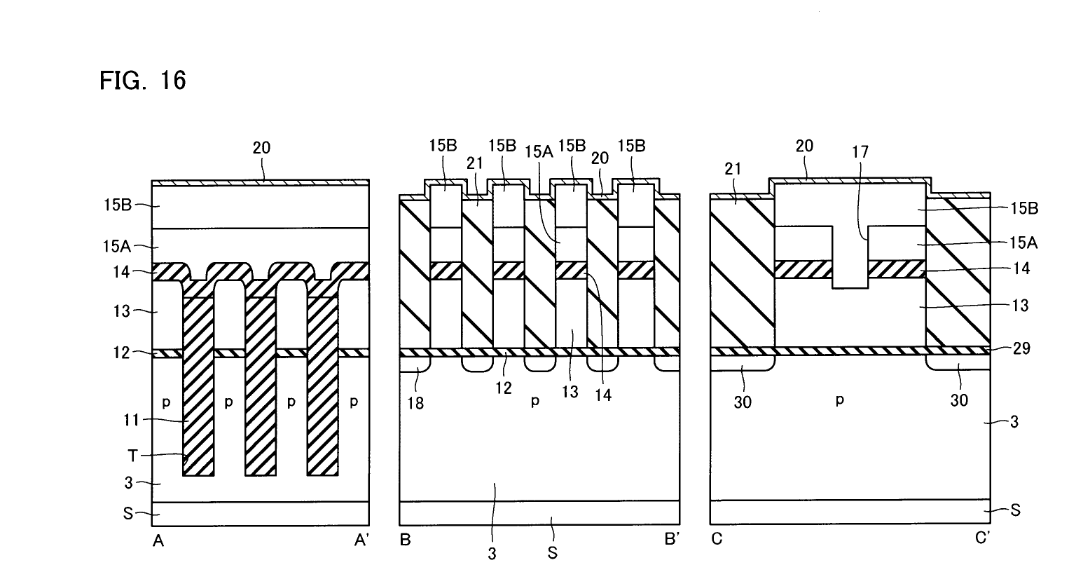

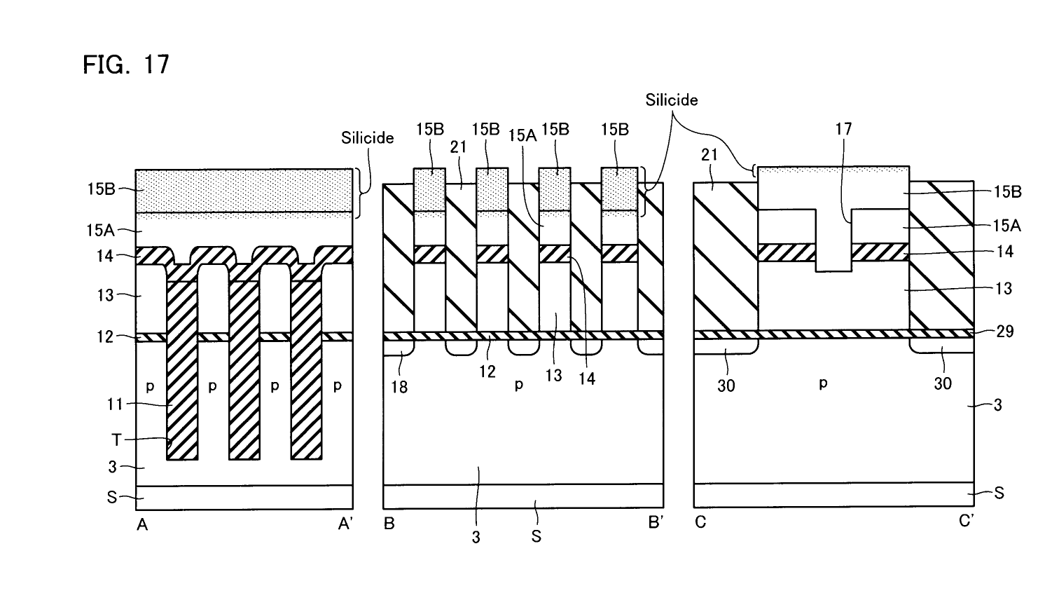

If an amount of the metal film 20 formed by sputtering in the memory cell region 100 is reduced, the polysilicon films 15A and 15B can be prevented from being fully silicided. However, if the amount of the metal film 20 is reduced, it becomes impossible to form a sufficient amount of silicide in the peripheral circuit region 200. FIGS. 16 and 17 are views of the method of manufacturing in the comparative example for explaining this problem. FIG. 16 shows a state where the amount of the metal film formed by sputtering is reduced in the method of manufacturing a nonvolatile semiconductor memory device in the comparative example.

Next, as shown in FIG. 17, an RTP method is used to silicide the polysilicon films 15A and 15B. In the example shown in FIG. 17, the amount of the metal film 20 is small, hence the amount of metal atoms diffused is less than in the example shown in FIGS. 14 and 15. As a result, when the silicide process of a certain time has terminated, then, in the memory cell region 100, although part of the polysilicon film 15A is silicided, the silicide process terminates without silicide reaching as far as the inter-electrode insulating film 14.

In contrast, in the peripheral circuit region 200 shown in the C-C′ line cross-section, the amount of the metal film 20 is small, and the metal film 20 and the polysilicon film 15B are mainly in contact only at the upper surface of the polysilicon film 15B, hence metal is not sufficiently diffused within the polysilicon film 15B. As a result, an agglomeration of metal occurs on the polysilicon film 15B in the peripheral circuit region 200, and a sufficient amount of silicide cannot be formed in the polysilicon film. In this case, there is a risk that, when a contact is formed on the polysilicon film 15B in the peripheral circuit region 200 in a subsequent process, silicide does not function as a stopper in RIE. Even if it is attempted to form a contact reaching the polysilicon film 15B, there is a possibility that the silicide and polysilicon films 15A and 15B get penetrated through and that penetration proceeds further even as far as the inter-electrode insulating film 14, thereby generating a defect.

As described above, in the silicide process of a nonvolatile semiconductor memory device in the comparative example, even the thickness of the metal film 20 is increased to enable sufficient silicide to be formed in the field-effect transistor Tr in the peripheral circuit region 200, siliciding proceeds excessively in the memory cell transistor Mn in the memory cell region 100, resulting in occurrence of a void in the gate electrode. Conversely, even assuming that thickness of the metal film 20 is decreased to enable an appropriate amount of silicide to be formed in the memory cell transistor Mn, only an insufficient amount of silicide is formed in the field-effect transistor Tr. Hence, in the silicide process of a nonvolatile semiconductor memory device in the comparative example, it is not possible for a sufficient amount of silicide to be formed in the peripheral circuit region 200 while suppressing growth speed of silicide in the memory cell region 100.

In contrast, in the method of manufacturing in the present embodiment, the barrier film 16 for preventing growth of silicide is formed in the polysilicon film 15B. This barrier film 16 stops siliciding proceeding excessively in the memory cell region 100 and allows the polysilicon film to be silicided to a vicinity of the barrier film 16 in the peripheral circuit region 200. In the silicide process of the method of manufacturing in the present embodiment, the polysilicon films 15A and 15B in the memory cell region 100 are not fully silicided, and a void does not occur in the polysilicon films 15A and 15B due to excessive siliciding. In addition, agglomeration of metal in the peripheral circuit region 200 can also be prevented. Employing the method of manufacturing a nonvolatile semiconductor memory device in the present embodiment allows a sufficient amount of silicide to be formed in the peripheral circuit region 200 while suppressing growth speed of silicide in the memory cell region 100, and thereby allows operational characteristics of the memory cell transistor Mn and the field-effect transistor Tr to be improved.

[Other Examples of Nonvolatile Semiconductor Memory Device According to First Embodiment]

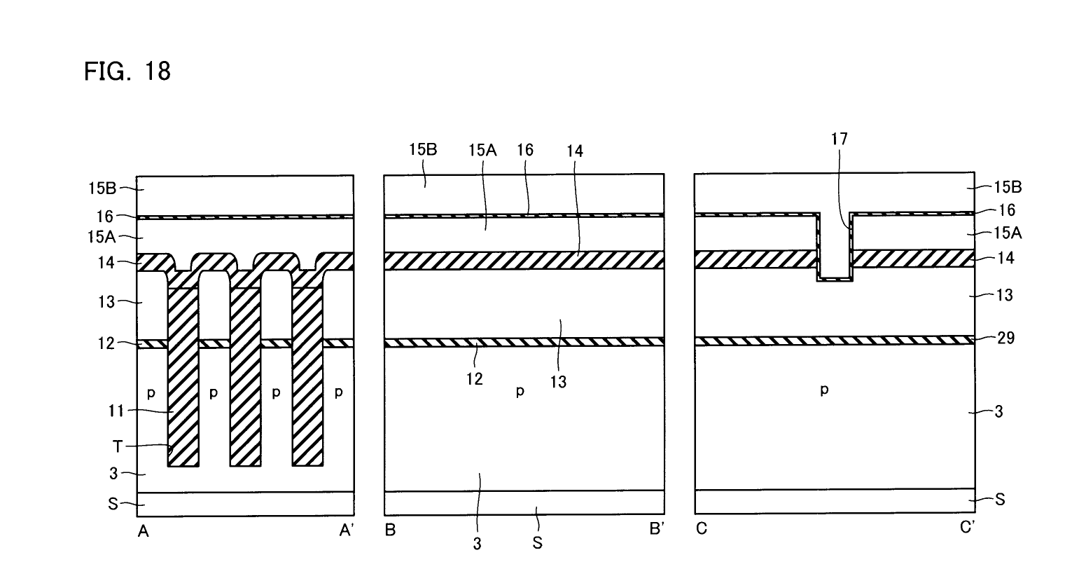

In the above-mentioned method of manufacturing in the first embodiment, the barrier film 16 is formed on the polysilicon film 15A, and then the opening 17 is formed (refer to FIGS. 8 and 9). This order of formation of the barrier film 16 and formation of the opening 17 can be changed. That is, it is possible that the opening penetrating the polysilicon film 15A and the inter-electrode insulating film 14 is formed, and then the barrier film 16 is formed. In this case, the barrier film 16 is formed also inside the opening 17. FIG. 18 is a view showing a state where the opening 17 and the barrier film 16 are formed by this method. As mentioned above, the barrier film 16 is set to a thickness that allows the polysilicon film 15A and the polysilicon film 15B to be conducting with each other. Therefore, since the polysilicon film 13 is also conducting with the polysilicon film 15A at a bottom of the opening 17 via the barrier film 16, a change in the order of formation of the barrier film 16 and formation of the opening 17 has no effect on operation of the nonvolatile semiconductor memory device. Apart from change in the order of formation of the barrier film 16 and formation of the opening 17, the nonvolatile semiconductor memory device can be formed by adopting a similar method to the above-mentioned method of manufacturing of the embodiment.

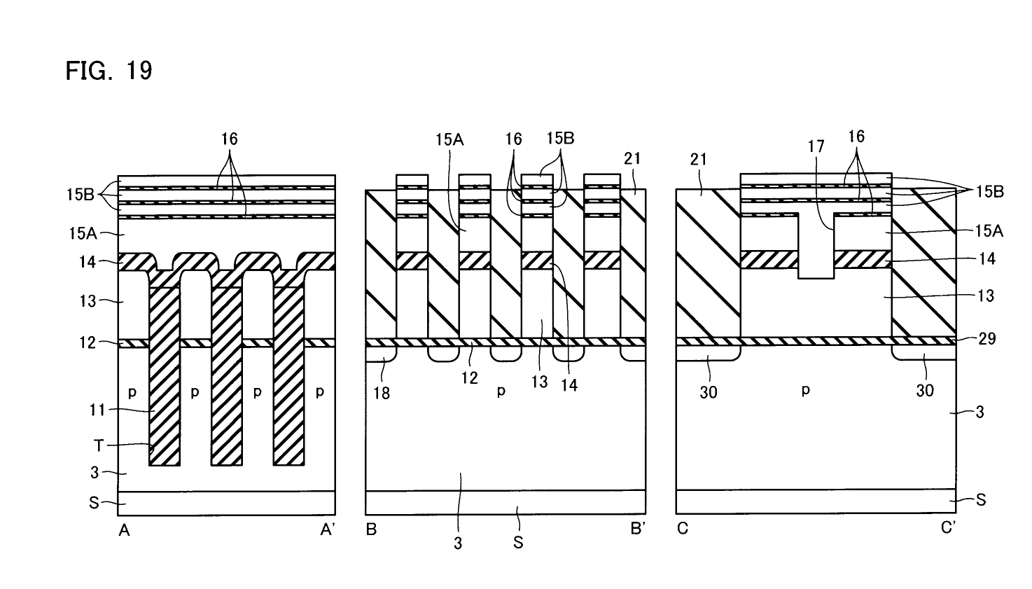

Moreover, in the method of manufacturing in the first embodiment, the barrier film 16 is described as being only one layer formed between the polysilicon films 15A and 15B. However, as shown in FIG. 19, the barrier film 16 may also be formed by dividing the process for stacking the polysilicon film 15B into multiple times, and performing interface treatment in each of the processes. This allows a plurality of barrier films 16 to be provided in the polysilicon film 15B. As a result, growth of silicide in the memory cell region 100 can be further suppressed.

### Second Embodiment

### Method of Manufacturing Nonvolatile Semiconductor Memory Device According to Second Embodiment

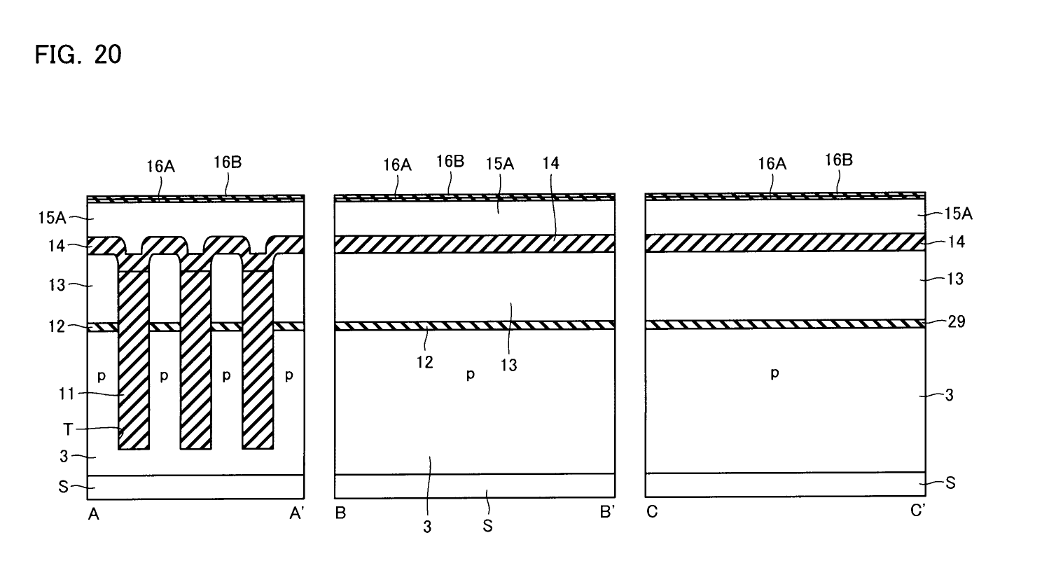

Next, a method of manufacturing a nonvolatile semiconductor memory device according to a second embodiment of the present invention is described with reference to FIGS. 20-23. The nonvolatile semiconductor memory device in the second embodiment differs from that of the first embodiment in utilizing a stacked film of a silicon oxide film and a silicon nitride film as the barrier film 16. Other configurations in the memory cell region 100 and the peripheral circuit region 200 of the nonvolatile semiconductor memory device in the second embodiment are similar to those of the above-mentioned first embodiment shown in FIGS. 1-6. Identical symbols are assigned to places corresponding to those in the first embodiment, and an explanation of those places is omitted.

Regarding subsequent drawings, FIGS. 20-23 are cross-sectional views of manufacturing processes of the memory cell transistor Mn formed in the memory cell region 100 and the field-effect transistor Tr formed in the peripheral circuit region 200. FIGS. 20-23 each show, in alignment, a cross-section taken along the line A-A′ shown in FIG. 2B, a cross-section taken along the line B-B′ shown in FIG. 2B, and a cross-section taken along the line C-C′ shown in FIG. 3. Note that, to simplify description, the cross-section taken along the line B-B′ omits the select gate transistor ST1 and shows only part of the memory cell Mn.

The method of manufacturing in the present embodiment is similar to that of the first embodiment up to the process for forming the stacking structure of the gate electrodes shown in FIG. 7. Next, as shown in FIG. 20, the barrier film 16 is formed on the polysilicon film 15A. In the method of manufacturing in the present embodiment, the barrier film 16 is formed as a stacked film of a silicon oxide film 16A and a silicon nitride film 16B. Film thickness of this stacked film is, for example, about 1.5-3.0 nm. These silicon oxide film 16A and silicon nitride film 16B suppress diffusion of metal atoms in the subsequent silicide process.

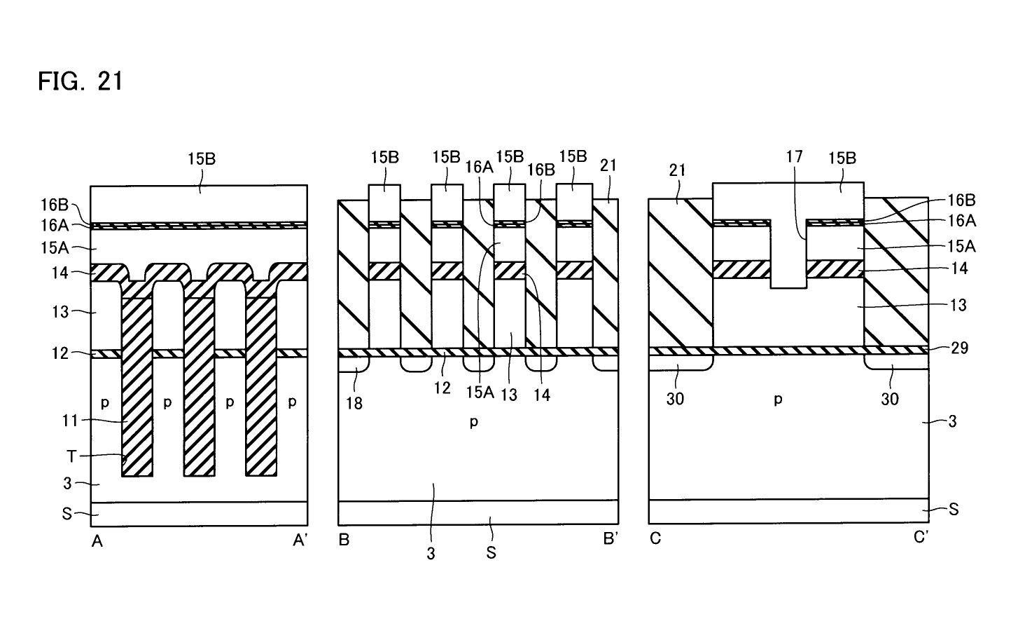

Subsequent processes of the method of manufacturing in the present embodiment comprise similar processes to those in the first embodiment. That is, as shown in FIG. 21, the silicon oxide film 16A, the silicon nitride film 16B, the polysilicon film 15A, and the inter-electrode insulating film 14 are penetrated to reach the polysilicon film 13, thereby forming the opening 17. The field-effect transistor Tr in the peripheral circuit region 200 has the polysilicon films 15A and 15B forming the upper gate electrode and the polysilicon film 13 forming the lower gate electrode electrically connected via this opening 17. Then, the polysilicon film 15B is deposited on the silicon oxide film 16A and the silicon nitride film 16B, so as to fill in the opening 17. The silicon oxide film 16A and the silicon nitride film 16B here have a thickness set to, for example, about 1.5-3.0 nm, but need only be set to a thickness that allows conducting between the polysilicon films 15A and 15B. Upon completion of processes shown later, these two layers of polysilicon films 15A and 15B become the control gate electrode in the memory cell transistor Mn or the upper gate electrode in the field-effect transistor Tr. Subsequently, a photolithography method and the RIE method are used to perform patterning, and the polysilicon films 15A and 15B, the silicon oxide film 16A, the silicon nitride film 16B, the inter-electrode insulating film 14, and the polysilicon film 13 in the memory cell region 100 and the peripheral circuit region 200 are etched sequentially. Then, the impurity diffusion region 18 and the impurity diffusion region 30 are formed by ion implantation, thereby forming the memory cell transistor Mn and the field-effect transistor Tr. When the field-effect transistor Tr is an NMOS transistor, the impurity diffusion region 30 is formed by ion implantation with, for example, arsenic (As) or phosphorus (P), and when the field-effect transistor Tr is a PMOS transistor, the impurity diffusion region 30 is formed by ion implantation with, for example, boron (B) or boron fluoride (BF₂). Next, the space between the patterned gate electrodes MGn in the memory cell region 100 and the patterned gate electrode PG in the peripheral circuit region 200 are filled in by the silicon oxide film 21. The gate electrodes MGn and PG are once all filled in by the silicon oxide film 21. Then, planarization is executed by CMP using a mask material (not shown) on the gate electrodes MGn and PG as a stopper. Next, etching back is performed by the RIE method to remove the mask material on the gate electrodes MGn and PG, and to form an oxide film between the gate electrodes MGn and PG such that part of a side surface of the polysilicon film 15B is left exposed.

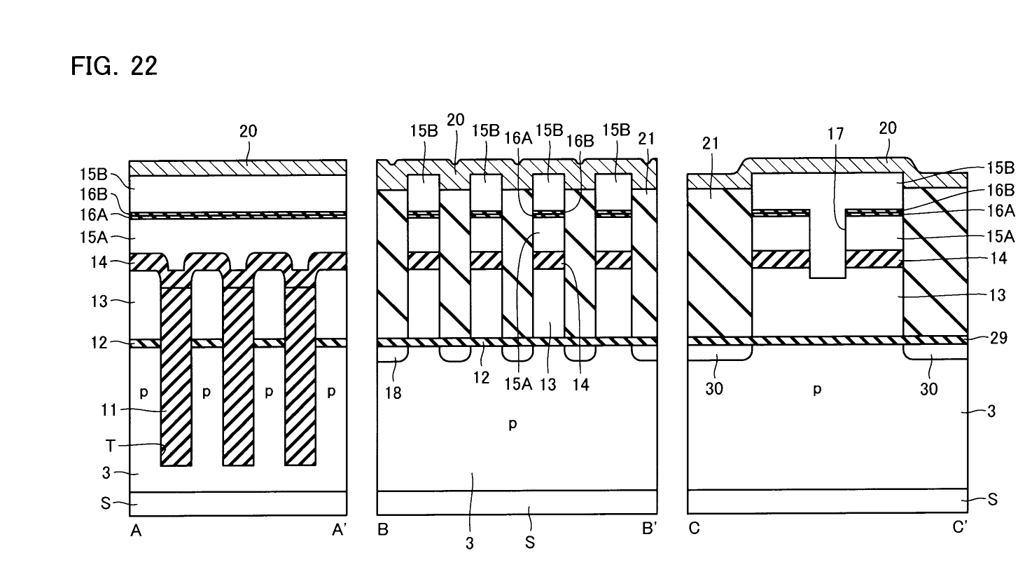

Next, as shown in FIG. 22, a metal film 20 is deposited by sputtering so as to cover the polysilicon film 15B. This metal film 20 is used for diffusing a metal into the polysilicon films 15A and 15B in the subsequent silicide process. As shown in the A-A′ line cross-section and the B-B′ line cross-section, the metal film 20 in the memory cell region 100 is provided so as to be in contact with an upper surface and part of a side surface of the polysilicon film 15B. At the same time, as shown in the C-C′ line cross-section, the metal film 20 in the peripheral circuit region 200 is in contact with an upper surface and part of a side surface of the polysilicon film 15B. Now, a gate length of the field-effect transistor Tr is long compared to a gate length of the memory cell transistor Mn. In the peripheral circuit region 200, the metal film 20 is in a state of being formed almost only on the upper surface of the polysilicon film 15B. In the peripheral circuit region 200, the proportion of metal with respect to the polysilicon film 15B is small compared to in the memory cell region 100.

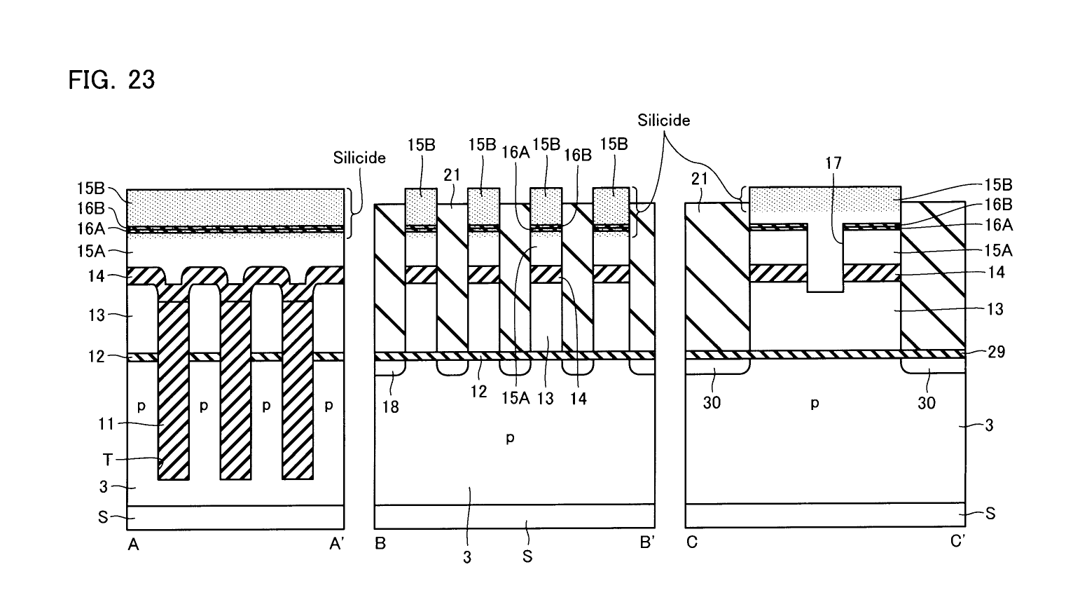

Next, as shown in FIG. 23, an RTP method is used to silicide the polysilicon films 15A and 15B. Now, in the memory cell region 100, the metal film 20 is in contact with the upper surface and the side surface of the polysilicon film 15B, whereby metal atoms are diffused from each of the surfaces. In the memory cell region 100, the proportion of metal with respect to the polysilicon film 15B is large, hence an amount of silicide extending into the polysilicon film 15B is large. On the other hand, in the peripheral circuit region 200, the metal film 20 is in contact mainly with the upper surface of the polysilicon film 15B. In the peripheral circuit region 200, the proportion of metal with respect to the polysilicon film 15B is small compared to in the memory cell region 100, hence an amount of silicide extending into the polysilicon film 15B is small.

Siliciding in the memory cell region 100 extends into an entirety of the polysilicon film 15B and reaches the silicon oxide film 16A and the silicon nitride film 16B. Likewise in the method of manufacturing in the present embodiment, diffusion of metal atoms in the memory cell region 100 is suppressed by the silicon oxide film 16A and the silicon nitride film 16B, whereby growth speed of silicide is slowed. As a result, when the silicide process of a certain time has terminated, then, in the memory cell region 100, although part of the polysilicon film 15A is silicided, the silicide process terminates without silicide reaching as far as the inter-electrode insulating film 14. Moreover, in the peripheral circuit region 200, growth speed of silicide is slow, hence the silicide process terminates prior to silicide reaching the silicon oxide film 16A and the silicon nitride film 16B.

Manufacturing processes subsequent to those described above comprise well-known manufacturing processes of a nonvolatile semiconductor memory device. The memory cell region 100 and the peripheral circuit region 200 are filled in by the silicon oxide film 21. Then, the contact hole 27 is opened, and the contact plug 28 is formed by filling in the contact hole 27 with the conductor. Upper layer wiring is formed in contact with this contact plug 28 and a passivation film is deposited. This enables the nonvolatile semiconductor memory device of the present embodiment to be manufactured.

[Advantages of Method of Manufacturing Nonvolatile Semiconductor Memory Device According to Second Embodiment]

In the method of manufacturing in the present embodiment, the barrier film 16 is provided as the stacked film of the silicon oxide film 16A and the silicon nitride film 16B. These silicon oxide film 16A and silicon nitride film 16B stop siliciding proceeding excessively in the memory cell region 100 and allow the polysilicon film to be silicided to a vicinity of the silicon oxide film 16A and the silicon nitride film 16B in the peripheral circuit region 200. Hence, a sufficient amount of silicide can be formed in the peripheral circuit region 200 while suppressing growth speed of silicide in the memory cell region 100, and operational characteristics of the memory cell transistor Mn and the field-effect transistor Tr can be improved.

[Other Example of Nonvolatile Semiconductor Memory Device According to Second Embodiment]

Note that the barrier film 16 is described as a stacked film of a silicon oxide film and a silicon nitride film. However, the barrier film 16 is not limited to this configuration, and a film having two layers of a silicon nitride film, or another stacked film may be used as the barrier film 16.

### Third Embodiment

### Method of Manufacturing Nonvolatile Semiconductor Memory Device According to Third Embodiment

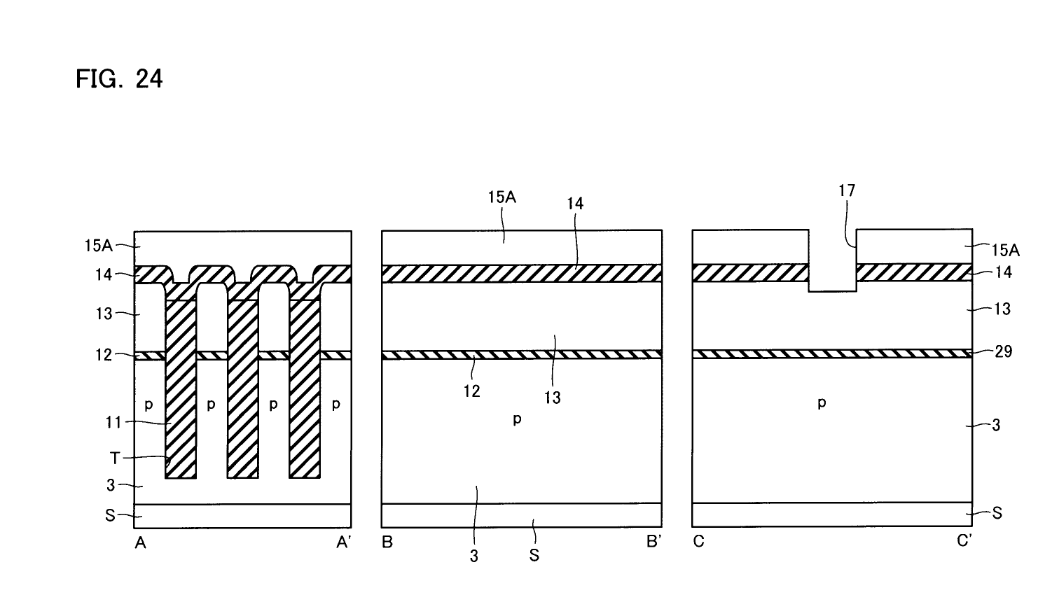

Next, a method of manufacturing a nonvolatile semiconductor memory device according to a third embodiment of the present invention is described with reference to FIGS. 24-28. The nonvolatile semiconductor memory device in the third embodiment is similar to that of the second embodiment in employing the stacked film of the silicon oxide film 16A and the silicon nitride film 16B as the barrier film 16. The method of manufacturing in the third embodiment differs from that of the second embodiment in changing the order of formation of the barrier film 16 and formation of the opening 17. Other configurations in the memory cell region 100 and the peripheral circuit region 200 of the nonvolatile semiconductor memory device in the third embodiment are similar to those of the above-mentioned first embodiment shown in FIGS. 1-6. Identical symbols are assigned to places corresponding to those in the first embodiment, and an explanation of those places is omitted.

Regarding subsequent drawings, FIGS. 24-28 are cross-sectional views of manufacturing processes of the memory cell transistor Mn formed in the memory cell region 100 and the field-effect transistor Tr formed in the peripheral circuit region 200. FIGS. 24-28 each show, in alignment, a cross-section taken along the line A-A′ shown in FIG. 2B, a cross-section taken along the line B-B′ shown in FIG. 2B, and a cross-section taken along the line C-C′ shown in FIG. 3. Note that, to simplify description, the cross-section taken along the line B-B′ omits the select gate transistor ST1 and shows only part of the memory cell Mn.

The method of manufacturing in the present embodiment is similar to that of the first embodiment up to the process for forming the stacking structure of the gate electrodes shown in FIG. 7. Next, as shown in FIG. 24, the polysilicon film 15A and the inter-electrode insulating film 14 are penetrated to reach the polysilicon film 13, thereby forming the opening 17. The field-effect transistor Tr in the peripheral circuit region 200 has the polysilicon films 15A and 15B forming the upper gate electrode and the polysilicon film 13 forming the lower gate electrode connected via this opening 17.

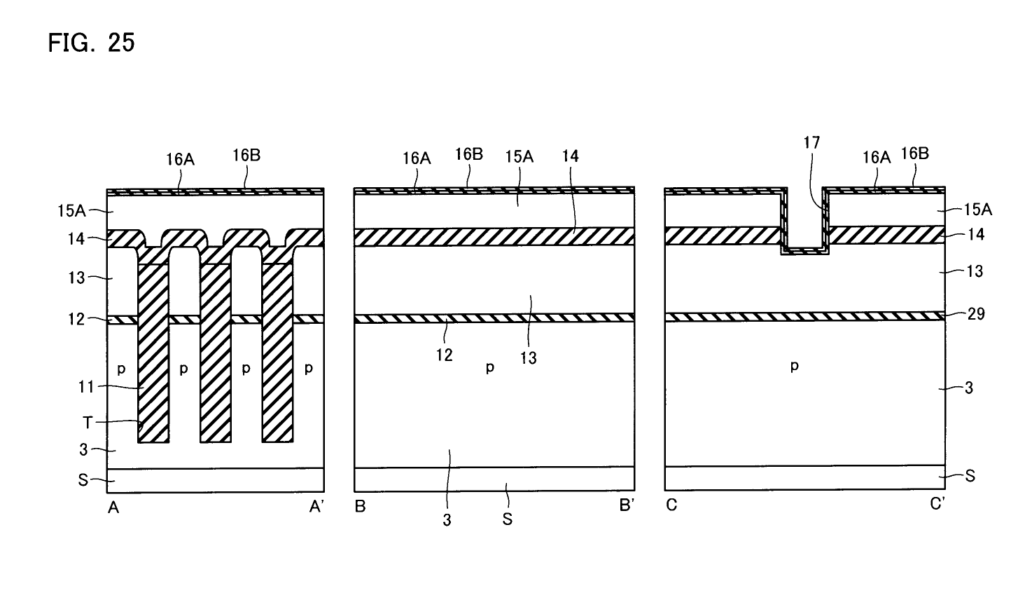

Next, as shown in FIG. 25, the barrier film 16 is formed on the polysilicon film 15A. In the method of manufacturing in the present embodiment, the barrier film 16 is formed as the stacked film of the silicon oxide film 16A and the silicon nitride film 16B. Film thickness of this stacked film is, for example, about 1.5-3.0 nm. These silicon oxide film 16A and silicon nitride film 16B suppress diffusion of metal atoms in the subsequent silicide process. In this case, the silicon oxide film 16A and the silicon nitride film 16B are formed also within the opening 17. As mentioned above, the barrier film 16 is set to a thickness that allows the polysilicon film 15A and the polysilicon film 15B to be conducting with each other. Therefore, since the polysilicon film 13 is also conducting with the polysilicon film 15A at a bottom of the opening 17 via the silicon oxide film 16A and the silicon nitride film 16B, a change in the order of formation of the silicon oxide film 16A and the silicon nitride film 16B and formation of the opening 17 has no effect on operation of the nonvolatile semiconductor memory device.

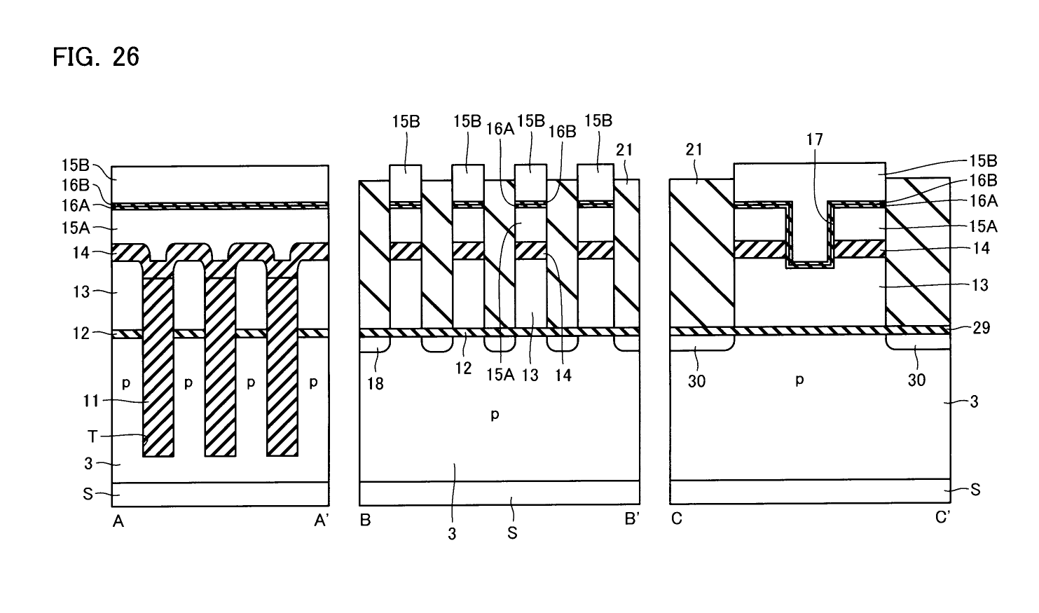

Subsequent processes of the method of manufacturing in the present embodiment comprise similar processes to those in the second embodiment. That is, as shown in FIG. 26, the polysilicon film 15B is deposited on the silicon oxide film 16A and the silicon nitride film 16B, so as to fill in the opening 17. The silicon oxide film 16A and the silicon nitride film 16B here have a thickness set to, for example, about 1.5-3.0 nm, but need only be set to a thickness that allows conducting between the polysilicon films 15A and 15B. Upon completion of processes shown later, these two layers of polysilicon films 15A and 15B become the control gate electrode in the memory cell transistor Mn or the upper gate electrode in the field-effect transistor Tr. Subsequently, a photolithography method and the RIE method are used to perform patterning, and the polysilicon films 15A and 15B, the silicon oxide film 16A, the silicon nitride film 16B, the inter-electrode insulating film 14, and the polysilicon film 13 in the memory cell region 100 and the peripheral circuit region 200 are etched sequentially. Then, the impurity diffusion region 18 and the impurity diffusion region 30 are formed by ion implantation, thereby forming the memory cell transistor Mn and the field-effect transistor Tr. When the field-effect transistor Tr is an NMOS transistor, the impurity diffusion region 30 is formed by ion implantation with, for example, arsenic (As) or phosphorus (P), and when the field-effect transistor Tr is a PMOS transistor, the impurity diffusion region 30 is formed by ion implantation with, for example, boron (B) or boron fluoride (BF₂). Next, the space between the patterned gate electrodes MGn in the memory cell region 100 and the patterned gate electrode PG in the peripheral circuit region 200 are filled in by the silicon oxide film 21. The gate electrodes MGn and PG are once all filled in by the silicon oxide film 21. Then, planarization is executed by CMP using a mask material (not shown) on the gate electrodes MGn and PG as a stopper. Next, etching back is performed by the RIE method to remove the mask material on the gate electrodes MGn and PG, and to form an oxide film between the gate electrodes MGn and PG such that part of a side surface of the polysilicon film 15B is left exposed.

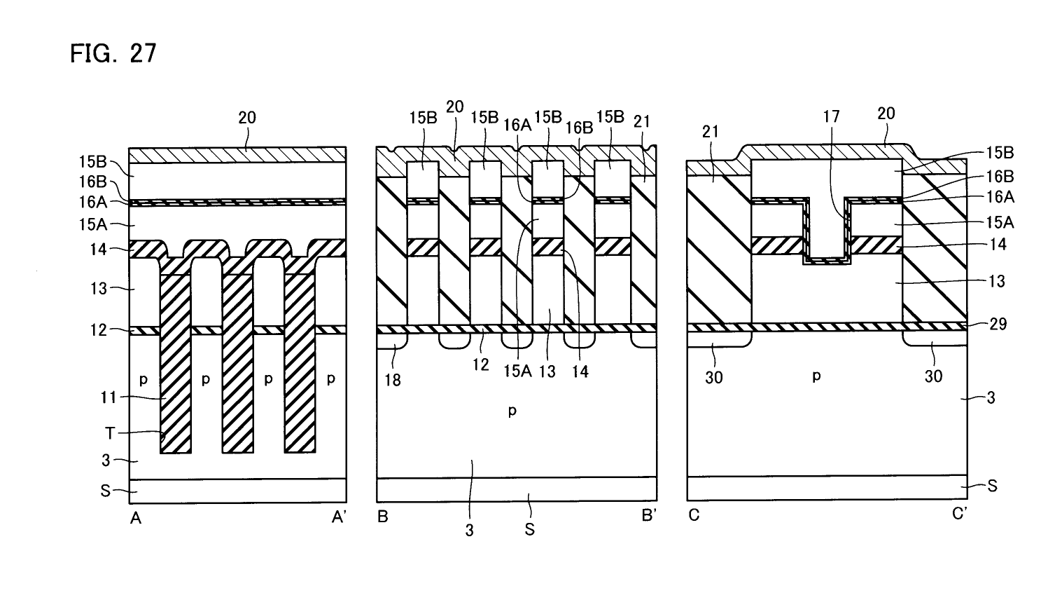

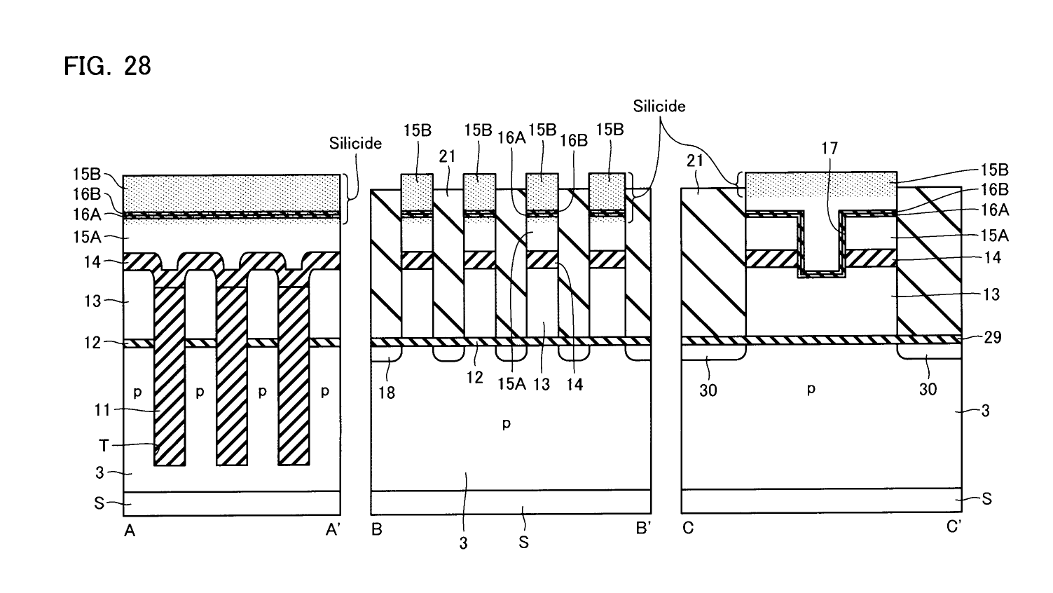

Next, as shown in FIG. 27, a metal film 20 is deposited by sputtering so as to cover the polysilicon film 15B. This metal film 20 is used for diffusing a metal into the polysilicon films 15A and 15B in the subsequent silicide process. As shown in the A-A′ line cross-section and the B-B′ line cross-section, the metal film 20 in the memory cell region 100 is provided so as to be in contact with an upper surface and part of a side surface of the polysilicon film 15B. At the same time, as shown in the C-C′ line cross-section, the metal film 20 in the peripheral circuit region 200 is in contact with an upper surface and part of a side surface of the polysilicon film 15B. Now, a gate length of the field-effect transistor Tr is long compared to a gate length of the memory cell transistor Mn. In the peripheral circuit region 200, the metal film 20 is in a state of being formed almost only on the upper surface of the polysilicon film 15B. In the peripheral circuit region 200, the proportion of metal with respect to the polysilicon film 15B is small compared to in the memory cell region 100.

Next, as shown in FIG. 28, an RTP method is used to silicide the polysilicon films 15A and 15B. Now, in the memory cell region 100, the metal film 20 is in contact with the upper surface and the side surface of the polysilicon film 15B, whereby metal atoms are diffused from each of the surfaces. In the memory cell region 100, the proportion of metal with respect to the polysilicon film 15B is large, hence an amount of silicide extending into the polysilicon film 15B is large. On the other hand, in the peripheral circuit region 200, the metal film 20 is in contact mainly with the upper surface of the polysilicon film 15B. In the peripheral circuit region 200, the proportion of metal with respect to the polysilicon film 15B is small compared to in the memory cell region 100, hence an amount of silicide extending into the polysilicon film 15B is small.

Siliciding in the memory cell region 100 extends into an entirety of the polysilicon film 15B and reaches the silicon oxide film 16A and the silicon nitride film 16B. Likewise in the method of manufacturing in the present embodiment, diffusion of metal atoms in the memory cell region 100 is suppressed by the silicon oxide film 16A and the silicon nitride film 16B, whereby growth speed of silicide is slowed. As a result, when the silicide process of a certain time has terminated, then, in the memory cell region 100, although part of the polysilicon film 15A is silicided, the silicide process terminates without silicide reaching as far as the inter-electrode insulating film 14. Moreover, in the peripheral circuit region 200, growth speed of silicide is slow, hence the silicide process terminates prior to silicide reaching the silicon oxide film 16A and the silicon nitride film 16B.

Manufacturing processes subsequent to those described above comprise well-known manufacturing processes of a nonvolatile semiconductor memory device. The memory cell region 100 and the peripheral circuit region 200 are filled in by the silicon oxide film 21. Then, the contact hole 27 is opened, and the contact plug 28 is formed by filling in the contact hole 27 with the conductor. Upper layer wiring is formed in contact with this contact plug 28 and a passivation film is deposited. This enables the nonvolatile semiconductor memory device of the present embodiment to be manufactured.

[Advantages of Method of Manufacturing Nonvolatile Semiconductor Memory Device According to Third Embodiment]

In the method of manufacturing in the present embodiment, the barrier film 16 is provided as the stacked film of the silicon oxide film 16A and the silicon nitride film 16B. These silicon oxide film 16A and silicon nitride film 16B stop siliciding proceeding excessively in the memory cell region 100 and allow the polysilicon film to be silicided to a vicinity of the silicon oxide film 16A and the silicon nitride film 16B in the peripheral circuit region 200. Hence, a sufficient amount of silicide can be formed in the peripheral circuit region 200 while suppressing growth speed of silicide in the memory cell region 100, and operational characteristics of the memory cell transistor Mn and the field-effect transistor Tr can be improved.

[Other Example of Nonvolatile Semiconductor Memory Device According to Third Embodiment]

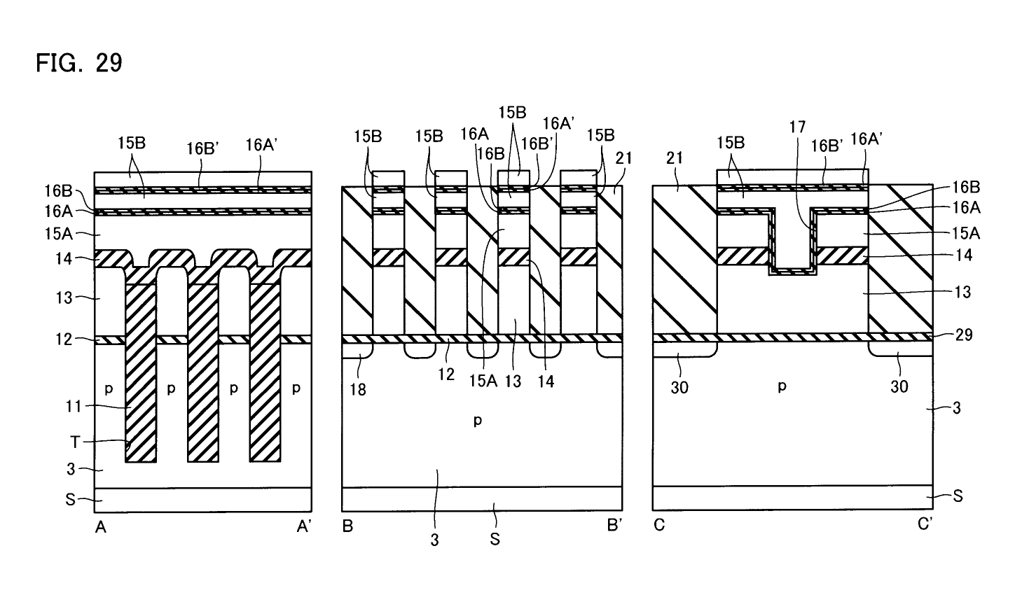

In the above-mentioned method of manufacturing in the third embodiment, the stacked silicon oxide film 16A and silicon nitride film 16B are described as being only one layer formed between the polysilicon films 15A and 15B. However, as shown in FIG. 29, a stacked film of a silicon oxide film 16A′ and a silicon nitride film 16B′ may also be formed by dividing the process for stacking the polysilicon film 15B into multiple times. This allows a plurality of barrier films (the stacked film of the silicon oxide film 16A and the silicon nitride film 16B, and the stacked film of the silicon oxide film 16A′ and the silicon nitride film 16B′) to be provided in the polysilicon film 15B. As a result, growth of silicide in the memory cell region 100 can be further suppressed.

### Fourth Embodiment

### Method of Manufacturing Nonvolatile Semiconductor Memory Device According to Fourth Embodiment

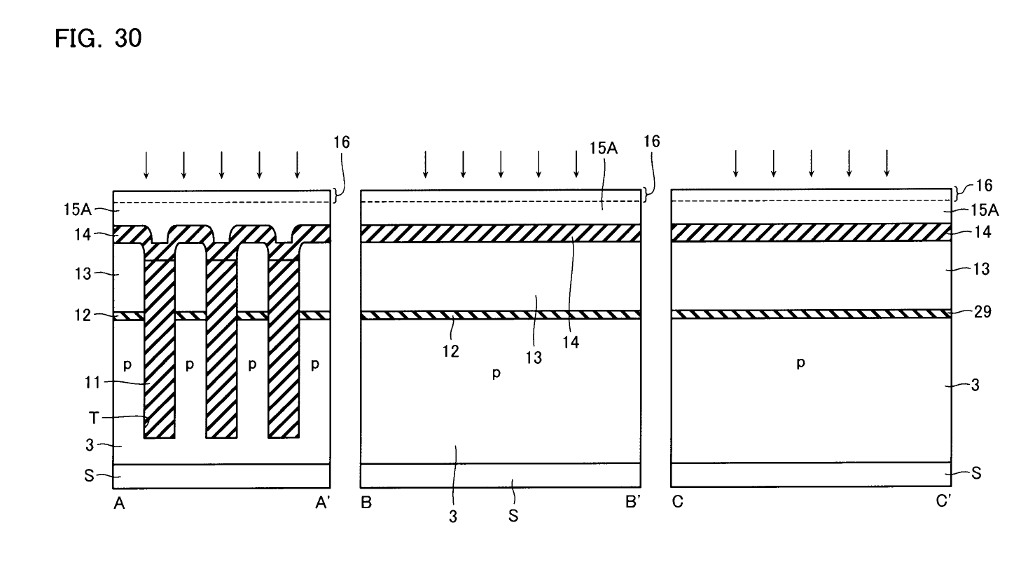

Next, a method of manufacturing a nonvolatile semiconductor memory device according to a fourth embodiment of the present invention is described with reference to FIGS. 30-33. The nonvolatile semiconductor memory device in the fourth embodiment differs from that of the first embodiment in employing a silicon carbide film and a silicon nitride film formed by doping a polysilicon film with carbon and nitrogen as the barrier film 16. Other configurations in the memory cell region 100 and the peripheral circuit region 200 of the nonvolatile semiconductor memory device in the fourth embodiment are similar to those of the above-mentioned first embodiment shown in FIGS. 1-6. Identical symbols are assigned to places corresponding to those in the first embodiment, and an explanation of those places is omitted.

Regarding subsequent drawings, FIGS. 30-33 are cross-sectional views of manufacturing processes of the memory cell transistor Mn formed in the memory cell region 100 and the field-effect transistor Tr formed in the peripheral circuit region 200. FIGS. 30-33 each show, in alignment, a cross-section taken along the line A-A′ shown in FIG. 2B, a cross-section taken along the line B-B′ shown in FIG. 2B, and a cross-section taken along the line C-C′ shown in FIG. 3. Note that, to simplify description, the cross-section taken along the line B-B′ omits the select gate transistor ST1 and shows only part of the memory cell Mn.

The method of manufacturing in the present embodiment is similar to that of the first embodiment up to the process for forming the stacking structure of the gate electrodes shown in FIG. 7. Next, as shown in FIG. 30, the barrier film 16 is formed on the polysilicon film 15A. In the method of manufacturing in the present embodiment, a surface of the polysilicon film 15A is doped with carbon and nitrogen to form a silicon carbide film and a silicon nitride film in the polysilicon film 15A. These silicon carbide film and silicon nitride film become the barrier film 16. The barrier film 16 suppresses diffusion of metal atoms in the subsequent silicide process.

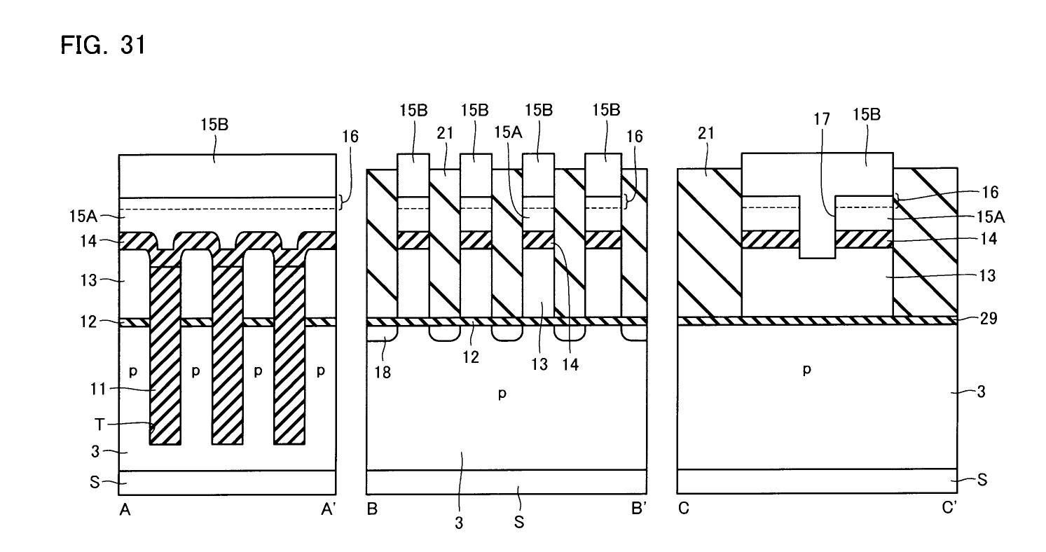

Subsequent processes of the method of manufacturing in the present embodiment comprise similar processes to those in the first embodiment. That is, as shown in FIG. 31, the barrier film 16, the polysilicon film 15A, and the inter-electrode insulating film 14 are penetrated to reach the polysilicon film 13, thereby forming the opening 17. The field-effect transistor Tr in the peripheral circuit region 200 has the polysilicon films 15A and 15B forming the upper gate electrode and the polysilicon film 13 forming the lower gate electrode electrically connected via this opening 17. Then, the polysilicon film 15B is deposited on the barrier film 16, so as to fill in the opening 17. The barrier film 16 need only be set to a thickness that allows conducting between the polysilicon films 15A and 15B. Upon completion of processes shown later, these two layers of polysilicon films 15A and 15B become the control gate electrode in the memory cell transistor Mn or the upper gate electrode in the field-effect transistor Tr. Subsequently, a photolithography method and the RIE method are used to perform patterning, and the polysilicon films 15A and 15B, the barrier film 16, the inter-electrode insulating film 14, and the polysilicon film 13 in the memory cell region 100 and the peripheral circuit region 200 are etched sequentially. Then, the impurity diffusion region 18 and the impurity diffusion region 30 are formed by ion implantation, thereby forming the memory cell transistor Mn and the field-effect transistor Tr. When the field-effect transistor Tr is an NMOS transistor, the impurity diffusion region 30 is formed by ion implantation with, for example, arsenic (As) or phosphorus (P), and when the field-effect transistor Tr is a PMOS transistor, the impurity diffusion region 30 is formed by ion implantation with, for example, boron (B) or boron fluoride (BF₂). Next, the space between the patterned gate electrodes MGn in the memory cell region 100 and the patterned gate electrode PG in the peripheral circuit region 200 are filled in by the silicon oxide film 21. The gate electrodes MGn and PG are once all filled in by the silicon oxide film 21. Then, planarization is executed by CMP using a mask material (not shown) on the gate electrodes MGn and PG as a stopper. Next, etching back is performed by the RIE method to remove the mask material on the gate electrodes MGn and PG, and to form an oxide film between the gate electrodes MGn and PG such that part of a side surface of the polysilicon film 15B is left exposed.

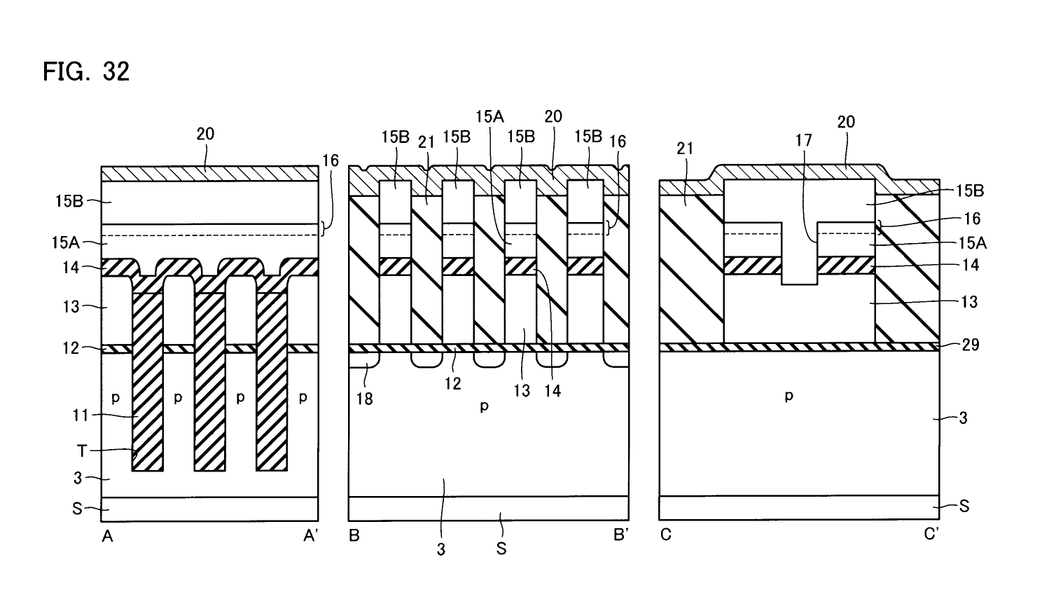

Next, as shown in FIG. 32, a metal film 20 is deposited by sputtering so as to cover the polysilicon film 15B. This metal film 20 is used for diffusing a metal into the polysilicon films 15A and 15B in the subsequent silicide process. As shown in the A-A′ line cross-section and the B-B′ line cross-section, the metal film 20 in the memory cell region 100 is provided so as to be in contact with an upper surface and part of a side surface of the polysilicon film 15B. At the same time, as shown in the C-C′ line cross-section, the metal film 20 in the peripheral circuit region 200 is in contact with an upper surface and part of a side surface of the polysilicon film 15B. Now, a gate length of the field-effect transistor Tr is long compared to a gate length of the memory cell transistor Mn. In the peripheral circuit region 200, the metal film 20 is in a state of being formed almost only on the upper surface of the polysilicon film 15B. In the peripheral circuit region 200, the proportion of metal with respect to the polysilicon film 15B is small compared to in the memory cell region 100.

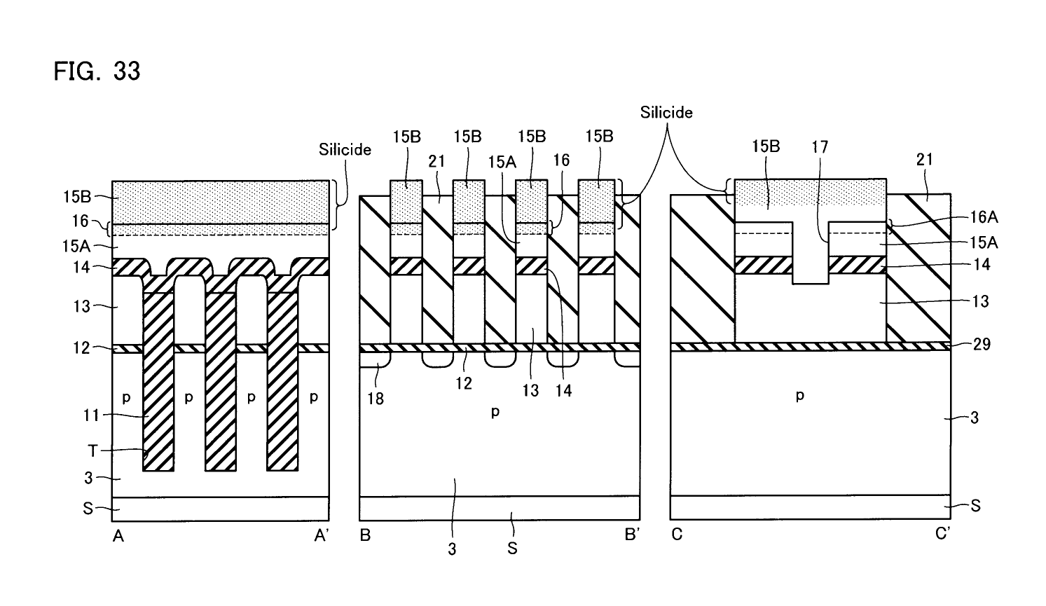

Next, as shown in FIG. 33, an RTP method is used to silicide the polysilicon films 15A and 15B. Now, in the memory cell region 100, the metal film 20 is in contact with the upper surface and the side surface of the polysilicon film 15B, whereby metal atoms are diffused from each of the surfaces. In the memory cell region 100, the proportion of metal with respect to the polysilicon film 15B is large, hence an amount of silicide extending into the polysilicon film 15B is large. On the other hand, in the peripheral circuit region 200, the metal film 20 is in contact mainly with the upper surface of the polysilicon film 15B. In the peripheral circuit region 200, the proportion of metal with respect to the polysilicon film 15B is small compared to in the memory cell region 100, hence an amount of silicide extending into the polysilicon film 15B is small.

Siliciding in the memory cell region 100 extends into an entirety of the polysilicon film 15B and reaches the barrier film 16. Likewise in the method of manufacturing in the present embodiment, diffusion of metal atoms in the memory cell region 100 is suppressed by the barrier film 16, whereby growth speed of silicide is slowed. As a result, when the silicide process of a certain time has terminated, then, in the memory cell region 100, although part of the polysilicon film 15A is silicided, the silicide process terminates without silicide reaching as far as the inter-electrode insulating film 14. Moreover, in the peripheral circuit region 200, growth speed of silicide is slow, hence the silicide process terminates prior to silicide reaching the barrier film 16.

Manufacturing processes subsequent to those described above comprise well-known manufacturing processes of a nonvolatile semiconductor memory device. The memory cell region 100 and the peripheral circuit region 200 are filled in by the silicon oxide film 21. Then, the contact hole 27 is opened, and the contact plug 28 is formed by filling in the contact hole 27 with the conductor. Upper layer wiring is formed in contact with this contact plug 28 and a passivation film is deposited. This enables the nonvolatile semiconductor memory device of the present embodiment to be manufactured.

[Advantages of Method of Manufacturing Nonvolatile Semiconductor Memory Device According to Fourth Embodiment]

In the method of manufacturing in the present embodiment, the barrier film 16 is provided as a silicon carbide film and a silicon nitride film formed by doping a polysilicon film with carbon and nitrogen. This barrier film 16 stops siliciding proceeding excessively in the memory cell region 100 and allows the polysilicon film to be silicided to a vicinity of the barrier film in the peripheral circuit region 200. Hence, a sufficient amount of silicide can be formed in the peripheral circuit region 200 while suppressing growth speed of silicide in the memory cell region 100, and operational characteristics of the memory cell transistor Mn and the field-effect transistor Tr can be improved.

[Other Examples of Nonvolatile Semiconductor Memory Device According to Fourth Embodiment]

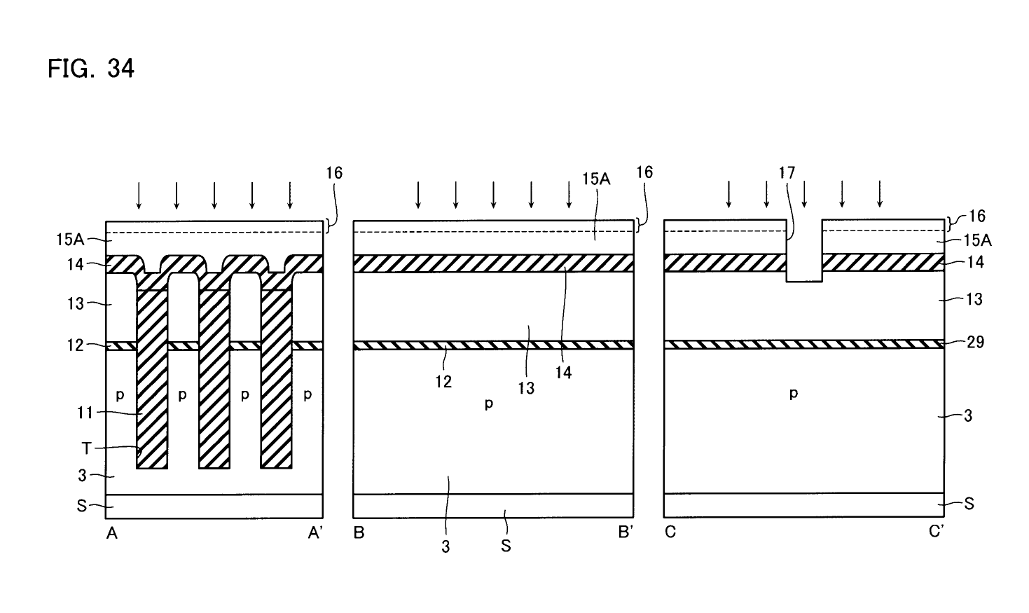

In the above-mentioned method of manufacturing in the fourth embodiment, the barrier film 16 is formed on the polysilicon film 15A, and then the opening 17 is formed (refer to FIGS. 30 and 31). This order of formation of the barrier film 16 and formation of the opening 17 can be changed. That is, it is possible that the opening penetrating the polysilicon film 15A and the inter-electrode insulating film 14 is formed, and then the barrier film 16 is formed. FIG. 34 is a view showing a state where the opening 17 is formed, and then the barrier film 16 is formed by doping the polysilicon film with carbon and nitrogen. Apart from change in the order of formation of the barrier film 16 and formation of the opening 17, the nonvolatile semiconductor memory device can be formed by adopting a similar method to the above-mentioned method of manufacturing of the embodiment shown in FIG. 32 and thereafter.

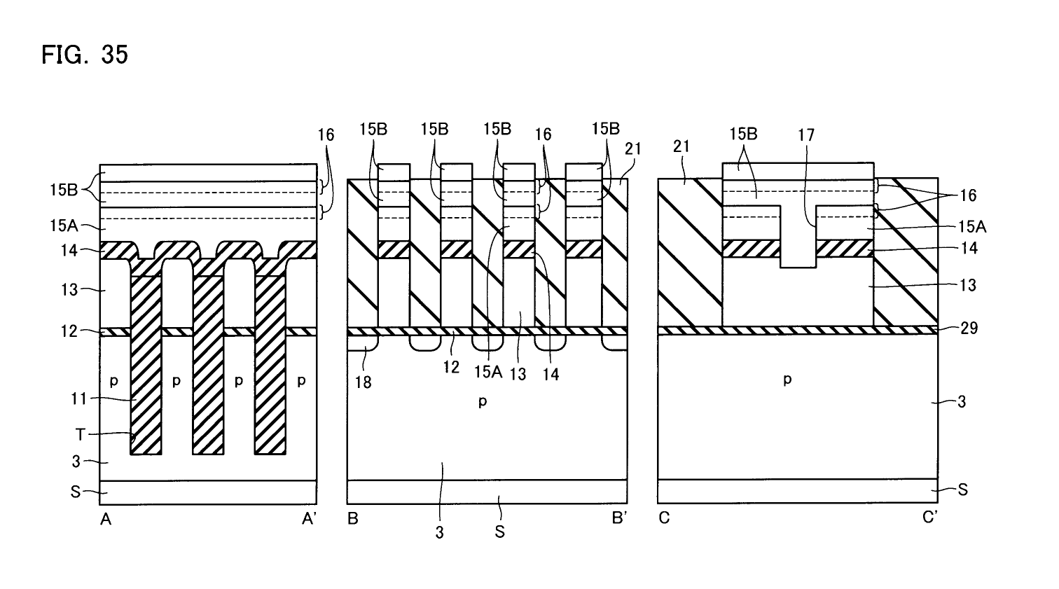

Moreover, in the method of manufacturing in the fourth embodiment, the barrier film 16 is described as being only one layer formed between the polysilicon films 15A and 15B. However, as shown in FIG. 35, the barrier film 16 may also be formed by dividing the process for stacking the polysilicon film 15B into multiple times, and doping the polysilicon film 15B with carbon and nitrogen in each of the processes. This allows a plurality of barrier films 16 to be provided in the polysilicon film 15B. As a result, growth of silicide in the memory cell region 100 can be further suppressed.

This concludes description of embodiments of the present invention, but it should be noted that the present invention is not limited to the above-described embodiments, and that various alterations, additions, combinations, and so on, are possible within a range not departing from the scope and spirit of the invention. For example, the number of memory cell transistors Mn connected in series between the select gate transistors ST1 and ST2 need only be a plurality and is not limited to sixteen.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor substrate;
a memory cell transistor formed in a memory cell region and including: a floating gate electrode formed on the semiconductor substrate via a first gate insulating film; a first inter-electrode insulating film disposed on the floating gate electrode; and a control gate electrode disposed on the first inter-electrode insulating film; and
a field-effect transistor formed in a peripheral circuit region and including: a lower gate electrode formed on the semiconductor substrate via a second gate insulating film; a second inter-electrode insulating film disposed on the lower gate electrode and having an opening; and an upper gate electrode disposed on the second inter-electrode insulating film and electrically connected to the lower gate electrode via the opening,
the control gate electrode and the upper gate electrode being formed by a plurality of conductive films that are stacked,
the control gate electrode and the upper gate electrode including a barrier film formed in at least one of interfaces between the stacked plurality of conductive films and configured to suppress diffusion of metal atoms, and
the control gate electrode and the upper gate electrode having a part that is silicided.

2. The nonvolatile semiconductor memory device according to claim 1, wherein
the barrier film is a silicon oxide film.

3. The nonvolatile semiconductor memory device according to claim 1, wherein
the barrier film is a silicon oxide film and a silicon nitride film that are stacked.

4. The nonvolatile semiconductor memory device according to claim 1, wherein
the barrier film is a silicon carbide film and a silicon nitride film that are configured by the conductive film doped with carbon and nitrogen.

5. The nonvolatile semiconductor memory device according to claim 1, wherein
the control gate electrode and the upper gate electrode are formed by at least three layers or more of the conductive films, and
the barrier film is provided in the interfaces between the plurality of conductive films.

6. The nonvolatile semiconductor memory device according to claim 1, wherein
the barrier film is formed also on an inside of the opening.

7. A method of manufacturing a nonvolatile semiconductor memory device, comprising:
forming a first conductive film in a memory cell region and a peripheral circuit region;
forming an inter-electrode insulating film on the first conductive film;
forming a second conductive film on the inter-electrode insulating film;
forming a barrier film on the second conductive film, the barrier film suppressing diffusion of metal atoms;
forming an opening configured to penetrate the barrier film, the second conductive film, and the inter-electrode insulating film to reach the first conductive film, in the peripheral circuit region;
forming a third conductive film on the barrier film;
patterning the third conductive film, the barrier film, the second conductive film, the inter-electrode insulating film, and the first conductive film in the memory cell region and the peripheral circuit region to form a memory cell transistor in the memory cell region, the memory cell transistor including a floating gate electrode, a first inter-electrode insulating film on the floating gate electrode, and a control gate electrode on the first inter-electrode insulating film, and to form a field-effect transistor in the peripheral circuit region, the field-effect transistor including a lower gate electrode, a second inter-electrode insulating film having the opening, and an upper gate electrode on the second inter-electrode insulating film; and
siliciding part of the third conductive film and the second conductive film in the memory cell region and the peripheral circuit region.

8. The method of manufacturing a nonvolatile semiconductor memory device according to claim 7, wherein
the barrier film is an oxide film formed by an interface treatment prior to a conductive film being stacked.

9. The method of manufacturing a nonvolatile semiconductor memory device according to claim 7, wherein
the barrier film is a silicon oxide film and a silicon nitride film that are stacked.

10. The method of manufacturing a nonvolatile semiconductor memory device according to claim 7, wherein
the barrier film is a silicon carbide film and a silicon nitride film that are configured by a conductive film doped with carbon and nitrogen.

11. The method of manufacturing a nonvolatile semiconductor memory device according to claim 7, wherein
forming the barrier film and forming the third conductive film are repeated alternately a certain number of times.

12. The method of manufacturing a nonvolatile semiconductor memory device according to claim 7, wherein
the barrier film is formed with a thickness allowing electrical conduction between the second conductive film and the third conductive film.

13. The method of manufacturing a nonvolatile semiconductor memory device according to claim 7, wherein
the siliciding is controlled to terminate before the siliciding reaches the first inter-electrode insulating film.

14. A method of manufacturing a nonvolatile semiconductor memory device, comprising:
forming a first conductive film in a memory cell region and a peripheral circuit region;
forming an inter-electrode insulating film on the first conductive film;
forming a second conductive film on the inter-electrode insulating film;
forming an opening configured to penetrate the second conductive film and the inter-electrode insulating film to reach the first conductive film, in the peripheral circuit region;
forming a barrier film on the second conductive film, the barrier film suppressing diffusion of metal atoms;
forming a third conductive film on the barrier film;
patterning the third conductive film, the barrier film, the second conductive film, the inter-electrode insulating film, and the first conductive film in the memory cell region and the peripheral circuit region to form a memory cell transistor in the memory cell region, the memory cell transistor including a floating gate electrode, a first inter-electrode insulating film on the floating gate electrode, and a control gate electrode on the first inter-electrode insulating film, and to form a field-effect transistor in the peripheral circuit region, the field-effect transistor including a lower gate electrode, a second inter-electrode insulating film having the opening, and an upper gate electrode on the second inter-electrode insulating film; and
siliciding part of the third conductive film and the second conductive film in the memory cell region and the peripheral circuit region.

15. The method of manufacturing a nonvolatile semiconductor memory device according to claim 14, wherein
the barrier film is an oxide film formed by an interface treatment prior to a conductive film being stacked.

16. The method of manufacturing a nonvolatile semiconductor memory device according to claim 14, wherein
the barrier film is a silicon oxide film and a silicon nitride film that are stacked.

17. The method of manufacturing a nonvolatile semiconductor memory device according to claim 14, wherein
the barrier film is a silicon carbide film and a silicon nitride film that are configured by a conductive film doped with carbon and nitrogen.

18. The method of manufacturing a nonvolatile semiconductor memory device according to claim 14, wherein
forming the barrier film and forming the third conductive film are repeated alternately a certain number of times.

19. The method of manufacturing a nonvolatile semiconductor memory device according to claim 14, wherein
the barrier film is formed with a thickness allowing electrical conduction between the second conductive film and the third conductive film.

20. The method of manufacturing a nonvolatile semiconductor memory device according to claim 14, wherein
the siliciding is controlled to terminate before the siliciding reaches the first inter-electrode insulating film.
